(19) United States
(12) Patent Application Publication
(10) Pub. No.: US 2023/0034867 A1
(43) Pub. Date: Feb. 2, 2023

(54) WIRING SUBSTRATE AND METHOD OF MANUFACTURING THE SAME

(71) Applicant: NEC Corporation, Minato-ku, Tokyo (JP)

(72) Inventors: Suguru WATANABE, Tokyo (JP); Takanori Nishi, Tokyo (JP)

(73) Assignee: NEC Corporation, Minato-ku, Tokyo (JP)

(21) Appl. No.: 17/789,308

(22) PCT Filed: Jan. 10, 2020
(86) PCT No.: PCT/JP2020/000733

§ 371 Date: Jun. 27, 2022

(51) Int. Cl. H01L 23/14; H01L 23/498; H01L 21/48

(52) U.S. Cl. CPC H01L 23/147; H01L 23/49827; H01L 23/49816; H01L 21/486

(57) ABSTRACT

A wiring substrate capable of providing a through electrode having an insulating layer with a small dielectric loss is provided. A wiring substrate (50) includes a silicon substrate (40) formed of silicon whose electrical resistivity is 1000 Ω·cm or larger and a through electrode (100) formed in the silicon substrate (40). The through electrode (100) is formed of a central conductor (110) that penetrates through the silicon substrate (40) and an external conductor (120, 130, 140) formed around the central conductor (110). The central conductor (110) and the external conductor (120, 130, 140) are electrically insulated from each other by the silicon substrate (40).

### TECHNICAL FIELD

The present disclosure relates to a wiring substrate and a method of manufacturing the same.

### BACKGROUND ART

Through electrodes (e.g., Through Silicon Vias (TSVs)) for electrically connecting together a front surface and a rear surface of a substrate have been known. In circuits that handle high-frequency signals, through electrodes may each be a coaxial-type TSV, which is formed of a central conductor and an external conductor which is provided around the central conductor in order to prevent electromagnetic leakage and crosstalk related to the leakage. The “coaxial-type” is not limited to a case in which the central conductor and the external conductor are concentric.

With regard to the above technique, Patent Literature 1 discloses a signal transmission element such as a coaxial line. In the signal transmission element according to Patent Literature 1, a first conductor and a second conductor are coaxially disposed with a ring-shaped dielectric layer (insulating layer) therebetween. The insulating layer has a structure in which it is completely filled up with amorphous silica (SiO₂) by reacting an organic Si compound with Si particles.

Further, Patent Literature 2 discloses a device including a substrate having a through substrate via structure. The device according to Patent Literature 2 includes an outer conductive layer disposed in the substrate, an outer insulating layer, an inner insulating layer, and an inner conductive layer. The outer insulating layer is disposed in the substrate in such a way that it separates the outer conductive layer from the substrate. The inner insulating layer is disposed in the substrate in such a way that it separates the inner conductive layer from the outer conductive layer.

### CITATION LIST

### Patent Literature

[Patent Literature 1] Japanese Patent No. 5401617
[Patent Literature 2] Japanese Patent No. 5568644

### SUMMARY OF INVENTION

### Technical Problem

In the aforementioned Patent Literature, as SiO₂ or a resin is used in the insulating layer of the coaxial-type TSV, it is possible that a dielectric loss in the coaxial-type TSV may be too large. This can cause a problem, especially when high-frequency signals are transmitted through the coaxial-type TSV (through electrode). For example, in the superconducting quantum circuit, it is possible that the coherence time may be reduced due to a dielectric loss.

The present disclosure has been made in order to solve the aforementioned problem and the aim of the present disclosure is to provide a wiring substrate capable of providing a through electrode having an insulating layer with a small dielectric loss and a method of manufacturing the same.

### Solution to Problem

A wiring substrate according to the present disclosure includes: a silicon substrate formed of silicon whose electrical resistivity is 1000 Ω·cm or larger; and a through electrode formed in the silicon substrate, in which the through electrode is formed of a central conductor that penetrates through the silicon substrate and an external conductor formed around the central conductor, and the central conductor and the external conductor are electrically insulated from each other by the silicon substrate.

Further, a method of manufacturing a wiring substrate according to the present disclosure includes: forming a non-through hole for a central conductor of a through electrode by performing a surface treatment on a first surface of a silicon substrate formed of silicon whose electrical resistivity is 1000 Ω·cm or larger; forming the central conductor by filling the non-through hole with conductors by plating; forming at least one hole for an external conductor, which is a hole for an external conductor of the through electrode, around the central conductor by performing a surface treatment on at least a second surface, which is a surface opposite to the first surface of the silicon substrate; forming the external conductor by filling the hole for the external conductor with conductors by plating; and performing a surface treatment on the second surface in such a way that the central conductor is exposed in the second surface.

### Advantageous Effects of Invention

According to the present disclosure, it is possible to provide a wiring substrate capable of providing a through electrode having an insulating layer with a small dielectric loss and a method of manufacturing the same.

### BRIEF DESCRIPTION OF DRAWINGS

FIG. 1 is a view showing a superconducting circuit device;

FIG. 2 is a view showing a structure of a wiring substrate according to example embodiments;

FIG. 3 is a view showing the wiring substrate according to the first example embodiment;

FIG. 4 is a view showing a method of manufacturing the wiring substrate according to the first example embodiment;

FIG. 5 is a view showing the method of manufacturing the wiring substrate according to the first example embodiment;

FIG. 6 is a view showing the method of manufacturing the wiring substrate according to the first example embodiment;

FIG. 7 is a view showing the method of manufacturing the wiring substrate according to the first example embodiment;

FIG. 8 is a view showing the method of manufacturing the wiring substrate according to the first example embodiment;

FIG. 9 is a view showing the method of manufacturing the wiring substrate according to the first example embodiment;

FIG. 10 is a view showing the method of manufacturing the wiring substrate according to the first example embodiment;

FIG. 11 is a view showing the method of manufacturing the wiring substrate according to the first example embodiment;

FIG. 12 is a view showing a wiring substrate according to a second example embodiment;

FIG. 13 is a view for describing an effect of forming an external conductor according to the second example embodiment in the shape as shown in FIG. 12;

FIG. 14 is a view for describing an effect of forming the external conductor according to the second example embodiment in the shape as shown in FIG. 12;

FIG. 15 is a view for describing an effect of forming the external conductor according to the second example embodiment in the shape as shown in FIG. 12;

FIG. 16 is a view for describing an effect of forming the external conductor according to the second example embodiment in the shape as shown in FIG. 12;

FIG. 17 is a view for describing an implementation example of a through electrode according to the second example embodiment;

FIG. 18 is a view for describing an implementation example of the through electrode according to the second example embodiment;

FIG. 19 is a view for describing an implementation example of the through electrode according to the second example embodiment;

FIG. 20 is a view showing a wiring substrate according to a third example embodiment;

FIG. 21 is a view showing a method of manufacturing the wiring substrate according to the third example embodiment;

FIG. 22 is a view showing the method of manufacturing the wiring substrate according to the third example embodiment;

FIG. 23 is a view showing the method of manufacturing the wiring substrate according to the third example embodiment;

FIG. 24 is a view showing the method of manufacturing the wiring substrate according to the third example embodiment;

FIG. 25 is a view showing the method of manufacturing the wiring substrate according to the third example embodiment;

FIG. 26 is a view showing the method of manufacturing the wiring substrate according to the third example embodiment;

FIG. 27 is a view showing the method of manufacturing the wiring substrate according to the third example embodiment;

FIG. 28 is a view showing the method of manufacturing the wiring substrate according to the third example embodiment;

FIG. 29 is a view showing the method of manufacturing the wiring substrate according to the third example embodiment;

FIG. 30 is a view showing the method of manufacturing the wiring substrate according to the third example embodiment; and

FIG. 31 is a flowchart showing a method of manufacturing the wiring substrate according to example embodiments.

### EXAMPLE EMBODIMENTS

(Outline of Example Embodiments According to the Present Disclosure)

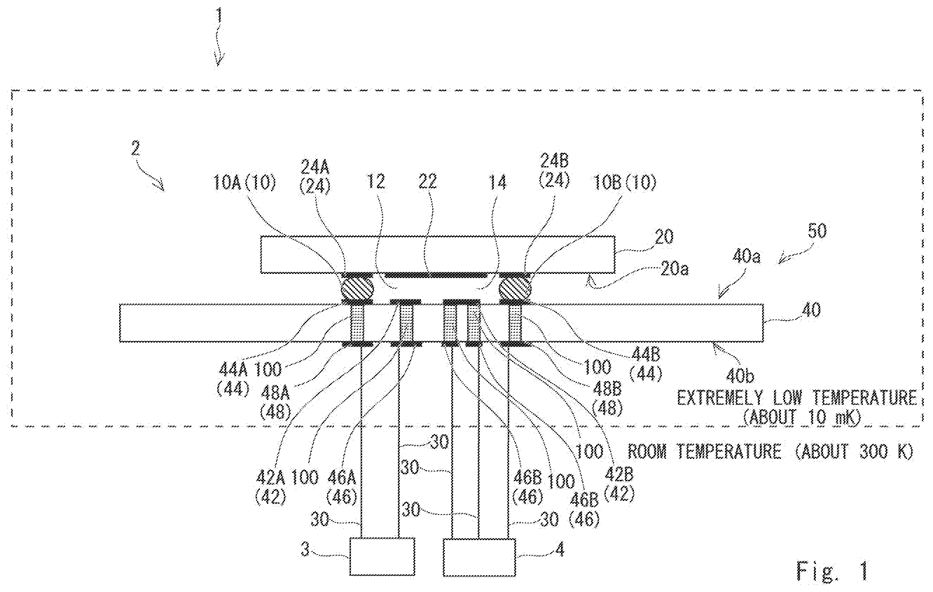

Prior to giving the description of example embodiments of the present disclosure, an outline of the example embodiments according to the present disclosure will be described. FIG. 1 is a view showing a superconducting circuit device 1. FIG. 1 is a cross-sectional view of the superconducting circuit device 1 when it is viewed from a side surface of the superconducting circuit device 1. The superconducting circuit device 1 is, for example, a quantum computer. The superconducting circuit device 1 includes a superconducting circuit mounting structure 2, a readout unit 3, and a control unit 4. The superconducting circuit mounting structure 2 includes a quantum circuit chip 20 and a silicon substrate 40. The quantum circuit chip 20 and the silicon substrate 40 are connected to each other by flip-chip connection.

The readout unit 3 and the control unit 4 are used under room temperature of about 300 K (K: Kelvin). On the other hand, the superconducting circuit mounting structure 2 (the quantum circuit chip 20 and the silicon substrate 40) are cooled down to an extremely low temperature of about 10 mK. Specifically, the silicon substrate 40 is in thermal contact with a cold stage (not shown). The cold stage is a stage of a freezing machine that is cooled down to a temperature of about 10 mK. Accordingly, the superconducting circuit mounting structure 2 may be cooled down to an extremely low temperature of about 10 mK.

The quantum circuit chip 20 includes a quantum circuit 22 made of a superconducting material. The quantum circuit 22 is formed on a front surface 20a of the quantum circuit chip 20 (a surface of the quantum circuit chip 20 that is opposed to the silicon substrate 40). Further, electrodes 24 (24A, 24B), which are conductive parts, are formed on the front surface 20a of the quantum circuit chip 20. The electrodes 24 are ground electrodes of the quantum circuit chip 20.

The quantum circuit 22 is a superconducting quantum circuit in which a plurality of superconducting quantum bits are integrated. The quantum circuit 22 is made of a superconducting material that is in a superconducting state in an extremely low temperature of about 10 mK. Each superconducting quantum bit is formed using a resonator. The temperature at which the quantum circuit 22 is operated is preferably 100 mK or lower. As long as this temperature is 100 mK or smaller, the lower this temperature is, the better. For example, the quantum circuit 22 is cooled down to an extremely low temperature of about 10 mK for operation.

The silicon substrate 40 is a silicon substrate. The silicon substrate 40 is a high-resistance silicon substrate formed of silicon whose electrical resistivity is 1000 Ω·cm or larger. Electrodes 42 (42A, 42B) and electrodes 44 (44A, 44B), which are conductive parts, are formed on a front surface 40a of the silicon substrate 40 (the surface of the silicon substrate 40 that is opposed to the quantum circuit chip 20). The electrodes 44 are ground electrodes of the silicon substrate 40. Further, as will be described later, the electrodes 42 and the quantum circuit 22 are coupled to each other in a non-contact manner by capacitive coupling 12 and inductive coupling 14.

A rear surface 40b of the silicon substrate 40 is in thermal contact with the cold stage. Further, electrodes 46 (46A, 46B) and electrodes 48 (48A, 48B), which are conductive parts, are formed on the rear surface 40b of the silicon substrate 40. The electrodes 48A and 48B are ground electrodes of the silicon substrate 40. The electrodes 46A and 48A are electrically connected to the readout unit 3 via a wire 30. Further, the electrodes 46B and 48B are electrically connected to the control unit 4 via the wire 30. Note that the wire 30 is, for example, a coaxial cable.

Further, through electrodes 100 that penetrate through the silicon substrate 40 are formed in the silicon substrate 40. Specifically, the through electrodes 100 are formed between the electrode 42A and the electrode 46A and between the electrode 42B and the electrode 46B. Likewise, the through electrodes 100 are formed between the electrode 44A and the electrode 48A and between the electrode 44B and the electrode 48B. The through electrodes 100 are, for example, coaxial TSVs. In this manner, a wiring substrate 50 includes the silicon substrate 40, the through electrodes 100, and the electrodes 42, 44, 46, and 48. In other words, the wiring substrate 50 includes at least the silicon substrate 40 and the through electrodes 100.

The electrodes 24 formed on the front surface 20a of the quantum circuit chip 20 and the electrodes 44 formed on the front surface 40a of the silicon substrate 40 are connected to each other by bumps 10. That is, the electrode 24A formed on the front surface 20a of the quantum circuit chip 20 and the electrode 44A formed on the front surface 40a of the silicon substrate 40 are connected to each other by a bump 10A. Likewise, the electrode 24B formed on the front surface 20a of the quantum circuit chip 20 and the electrode 44B formed on the front surface 40a of the silicon substrate 40 are connected to each other by a bump 10B.

Further, the conductive part of the quantum circuit 22 formed on the front surface 20a of the quantum circuit chip 20 and the electrode 42B formed on the front surface 40a of the silicon substrate 40 are opposed to each other. Then, the quantum circuit 22 and the electrode 42B are coupled to each other by the inductive coupling 14 via a mutual inductance that is present between the quantum circuit 22 and the electrode 42B. The inductive coupling here means non-contact coupling via the above mutual inductance.

Further, another conductive part of the quantum circuit 22 formed on the front surface 20a of the quantum circuit chip 20 and the electrode 42A formed on the front surface 40a of the silicon substrate 40 are opposed to each other. Then, the quantum circuit 22 and the electrode 42A are coupled to each other by the capacitive coupling 12 via a capacitance that is present between the quantum circuit 22 and the electrode 42A. The capacitive coupling means non-contact coupling via the above capacitance.

Then, by connecting the readout unit 3 and the control unit 4 to the electrodes 46 and 48 on the rear surface 40b of the silicon substrate 40, the quantum circuit 22 is controlled and the state of the quantum circuit 22 is read out. Specifically, control signals output from the control unit 4 pass through the through electrodes 100 and reach the electrode 42B formed on the front surface 40a of the silicon substrate 40. Then, the control signals are transmitted to the quantum circuit 22 via the inductive coupling 14. In this manner, the control unit 4 controls the quantum circuit 22 on the quantum circuit chip 20 via the through electrodes 100 and the inductive coupling. Likewise, the state of the quantum circuit 22 of the quantum circuit chip 20 is read out by the readout unit 3 through the electrode 42A formed on the front surface 40a of the silicon substrate 40 and the through electrodes 100 via the capacitive coupling 12 between the quantum circuit chip 20 and the silicon substrate 40. That is, the readout unit 3 reads out the state of the quantum circuit 22 via the through electrodes 100 and the capacitive coupling 12.

Since the control signals and readout signals are high-frequency signals whose frequency is equal to or higher than 1 GHz, the through electrodes 100 preferably have a coaxial structure (coaxial-type TSVs) in order to prevent electromagnetic leakage and crosstalk related to the leakage. In this description, the terms “coaxial-type” and “coaxial structure” are not limited to the case in which the central conductor and the external conductor are concentric. The “coaxial-type” and the “coaxial structure” simply mean a multi-layer structure including a central conductor and an external conductor.

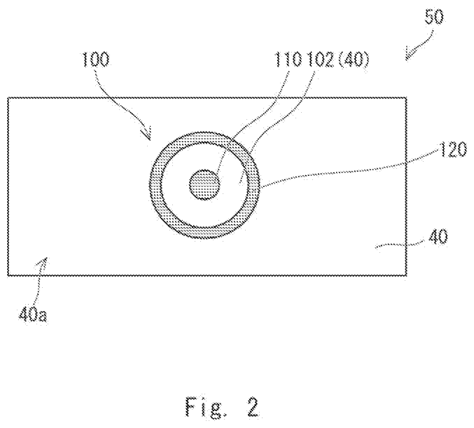

FIG. 2 is a view showing a structure of the wiring substrate 50 according to the example embodiments. FIG. 2 is a view of the wiring substrate 50 when it is viewed from the front surface 40a (or the rear surface 40b) of the silicon substrate 40. As described above, the wiring substrate 50 includes the silicon substrate 40 and the through electrodes 100. The through electrodes 100 each include a central conductor 110 that penetrates through the silicon substrate 40, and an external conductor 120. The external conductor 120 is formed around the central conductor 110. In other words, the through electrode 100 is formed of the central conductor 110 and the external conductor 120. Further, an insulating layer 102 is provided between the central conductor 110 and the external conductor 120. In the through electrode 100, at least the central conductor 110 penetrates through the silicon substrate 40. Therefore, the central conductor 110 and the external conductor 120 form the through electrode 100.

While the central conductor 110 is formed, for example, in a cylindrical shape, this structure is only an example. It is sufficient that the central conductor 110 at least have a columnar shape, not a cylindrical shape. The central conductor 110 functions as a core wire in which high-frequency signals are transmitted.

While the external conductor 120 is formed to have, for example, an annular shape in the cross section in a surface that is parallel to the front surface 40a, this structure is only an example. It is sufficient that, instead of an annular shape, the shape of the external conductor 120 (the cross-sectional shape of the external conductor 120) be a ring shape so as to surround at least the central conductor 110. That is, it is sufficient that the external conductor 120 have a hollow columnar shape (tubular shape). The external conductor 120 functions as a ground. While the external conductor 120 has a closed (continuous) shape when it is viewed from the front surface 40a of the silicon substrate 40 in FIG. 2, this shape is merely an example. A part of the external conductor 120 may have an opened shape (e.g., C shape) when it is viewed from the front surface 40a of the silicon substrate 40. Therefore, while a side surface of at least a part of the external conductor 120 penetrates through the silicon substrate 40, it is not necessary that the entire side surface of the external conductor 120 penetrates through the silicon substrate 40.

Since the central conductor 110, which is a core wire, is surrounded by the external conductor 120, which is a ground, electromagnetic leakage (this causes crosstalk) can be prevented. Further, by appropriately designing the dimension of the through electrode 100, reflection can be prevented. Therefore, for the transmission of high-frequency signals, the above-described coaxial-type TSV is preferably used since impedance needs to be adjusted to about 50Ω.

As described above, in the aforementioned Patent Literature, SiO₂ or a resin is used for the insulating layer of the coaxial-type TSV. In this case, it is possible that a dielectric loss in the coaxial-type TSV may be too large. Therefore, it is possible that the coaxial-type TSV according to Patent Literature described above cannot be used for a superconducting quantum computer (the superconducting circuit device 1). Specifically, the dielectric tangent of SiO₂ used in Patent Literature 1 and 2 is about 300×10⁻⁶. While a resin is used in the insulating layer in Patent Literature 1, the dielectric tangent of a resin is generally extremely large. In the superconducting quantum computer, it is difficult to use a material such as SiO₂ or a resin having a large dielectric tangent (therefore, a material having a large dielectric loss) since it reduces the coherence time of the quantum circuit. On the other hand, the dielectric tangent of highly crystalline silicon (Si) used for the silicon substrate is equal to or smaller than about 0.15×10⁻⁶, which is extremely small. Therefore, there is a limitation that the superconducting quantum computer must be manufactured using only metal and a highly crystalline silicon substrate. As described above, in order to put superconducting quantum computers into practical use, it is essential to provide a coaxial-type TSV (through electrode) having a small dielectric loss, which does not use an insulating material having a large dielectric loss.

In this example embodiment, the insulating layer 102 in the through electrode 100 is formed of the silicon substrate 40. That is, in the through electrode 100 of the wiring substrate 50 according to this example embodiment, the central conductor 110 and the external conductor 120 are electrically insulated from each other by the silicon substrate 40, which is a high-resistance silicon. According to this structure, it is possible to provide a through electrode having an insulating layer with a small dielectric loss. Therefore, transmission of high-frequency signals in the superconducting circuit device 1 can be appropriately conducted. Further, it is possible to appropriately secure the coherence time required for quantum computation of the superconducting circuit device 1.

Further, in this example embodiment, as will be described later, holes are formed on the both surfaces of the silicon substrate 40 by etching or the like, and these holes are filled with conductors by plating. It is therefore possible to manufacture a structure in which the central conductor 110 and the external conductor 120 are electrically insulated from each other by the silicon substrate 40, which is a high-resistance silicon.

### First Example Embodiment

Hereinafter, with reference to the drawings, example embodiments will be described. In order to clarify the explanation, the following descriptions and the drawings are omitted and simplified as appropriate. Further, throughout the drawings, the same components are denoted by the same reference symbols, and overlapping descriptions are omitted as necessary.

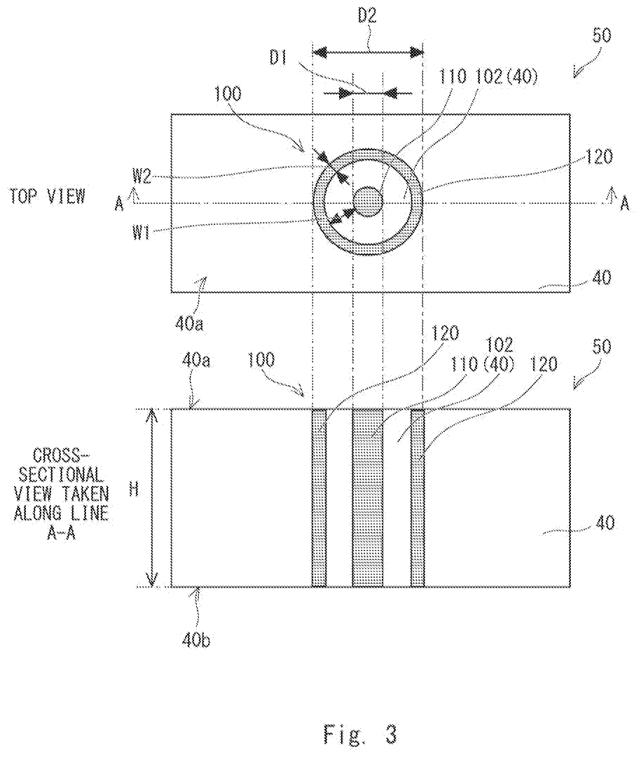

FIG. 3 is a view showing the wiring substrate 50 according to the first example embodiment. The upper view in FIG. 3 is a top view of the wiring substrate 50 when it is viewed from the front surface 40a of the silicon substrate 40 (the same is applied to the figures described below). Further, the lower view in FIG. 3 is a cross-sectional view of the cross section of the top view taken along the line A-A (the same is applied to the figures described below).

As described above, the wiring substrate 50 includes the silicon substrate 40 and the through electrodes 100. The silicon substrate 40 is formed of a high-resistance silicon having an electrical resistivity of 1000 Ω·cm or larger. The through electrodes 100 are, for example, coaxial-type TSVs. The through electrodes 100 each include the central conductor 110 that penetrates through the silicon substrate 40, and the external conductor 120. The external conductor 120 is formed around the central conductor 110. In other words, the through electrode 100 is formed of the central conductor 110 and the external conductor 120. Further, the insulating layer 102 is provided between the central conductor 110 and the external conductor 120 by the silicon substrate 40. That is, the central conductor 110 and the external conductor 120 are electrically insulated from each other by the silicon substrate 40. In the first example embodiment, the entire side surface of the external conductor 120 penetrates through the silicon substrate 40.

In the first example embodiment, the central conductor 110 is formed to have, for example, a cylindrical shape (columnar shape). Further, in the first example embodiment, the external conductor 120 is formed to have, for example, a hollow cylinder shape (tubular shape). In other words, the external conductor 120 according to the first example embodiment is formed to have a continuous annular shape (ring shape) in the cross section in a desired surface that is parallel to the front surface 40a of the silicon substrate 40. In other words, the external conductor 120 according to the first example embodiment is formed to surround the central conductor 110 in such a way that the external conductor 120 has a continuous ring shape. In other words, the external conductor 120 according to the first example embodiment is formed to have a continuous ring shape when it is viewed from the front surface 40a (or the rear surface 40b). In other words, the external conductor 120 according to the first example embodiment is formed around the central conductor 110 in such a way that the external conductor 120 has a continuous ring shape that circles around the central conductor 110. Therefore, the external conductor 120 according to the first example embodiment is formed in such a way that the cross-sectional shape in a desired surface that is parallel to the front surface 40a of the silicon substrate 40 becomes the same (ring shape) regardless of the position (that is, cutoff position) of the thickness direction of the silicon substrate 40. That is, the external conductor 120 according to the first example embodiment is formed to have a continuous shape in the thickness direction of the silicon substrate 40.

Note that the central conductor 110 and the external conductor 120 may be configured as follows. That is, the central conductor 110 has a shape of a first cylinder. The external conductor 120 is formed in a region surrounded by a second cylinder and a third cylinder, the second cylinder having a central axis that is the same as that of the first cylinder and having a diameter larger than the diameter D1 of the first cylinder, and the third cylinder having a central axis that is the same as that of the first cylinder and having a diameter D2 larger than the diameter of the second cylinder.

Incidentally, in order to integrate the through electrodes 100 in the silicon substrate 40 in a high density, the outermost diameter D2 of each of the through electrodes 100 is preferably made as small as possible. In order to minimize the outermost diameter D2, a width W2 of the external conductor 120 is preferably narrow. Specifically, the width W2 of the external conductor 120 is preferably 0.5 times as large or smaller than the diameter D1 (outer dimension) of the central conductor 110. In other words, the difference between the diameter of the third cylinder and the diameter of the second cylinder is 0.5 times as large or smaller than the diameter of the first cylinder.

Further, as described above, the central conductor 110 functions as a core wire in which high-frequency control signals and readout signals are transmitted, and the external conductor 120 functions as a ground. Therefore, the width W1 of the insulating layer is designed in such a way that the reflection becomes small when an electrical system with a characteristic impedance of, for example, 50Ω is connected to both ends of the through electrode 100 and a high-frequency signal of 1 GHz or larger is transmitted from one terminal to the other terminal of the through electrode 100. Specifically, the through electrode 100 is designed in such a way that S11 (reflection coefficient, or reflection characteristics of an input terminal) becomes equal to or smaller than −10 dB.

The thickness H of the silicon substrate 40 is about 300 μm. Further, the diameter D1 of the central conductor 110 is preferably 50 μm or smaller. Each of the central conductor 110 and the external conductor 120 is metal (conductor), preferably a normal metal (i.e., normal-conducting metal) such as copper (Cu) having a relatively low electrical resistivity, or metal such as niobium (Nb) or aluminum (Al) that is made of a superconducting material.

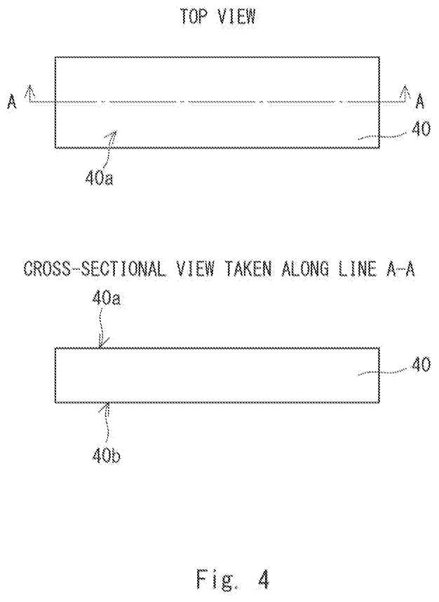

FIGS. 4 to 11 are views showing a method of manufacturing the wiring substrate 50 according to the first example embodiment. In FIGS. 4-11, upper views show views seen from the top (hereinafter these views will be referred to as top views) and lower views show cross-sectional views. The top views are views of the silicon substrate 40 when it is viewed from the front surface 40a of the silicon substrate 40 or from the rear surface 40b when the silicon substrate 40 is turned over.

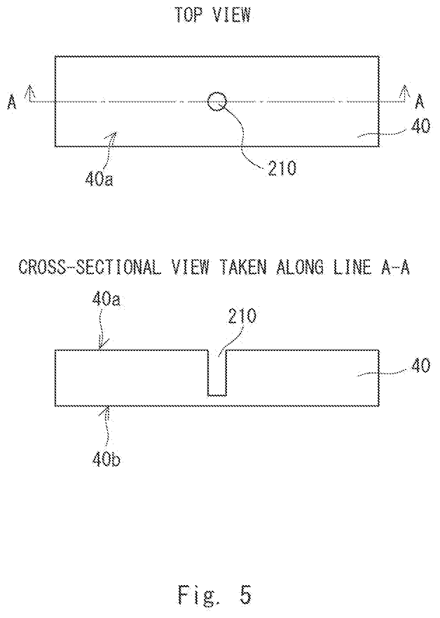

First, as shown in FIG. 4, the silicon substrate 40 is prepared. Next, as shown in FIG. 5, a non-through hole 210 (blind via) for the central conductor 110 is formed in the front surface 40a of the silicon substrate 40 by, for example, a surface treatment such as etching. That is, the front surface 40a (the first surface) of the silicon substrate 40 is subjected to a surface treatment, whereby the non-through hole 210 for the central conductor 110 is formed. The non-through hole 210 is a hole that does not penetrate through the silicon substrate 40.

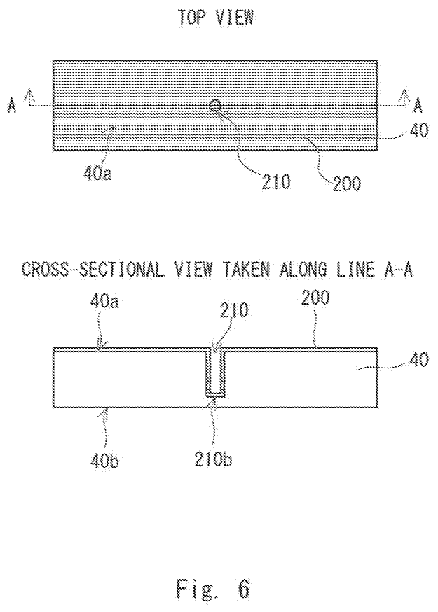

Next, as shown in FIG. 6, a seed layer 200 made of a conductor is formed on the entire front surface 40a of the silicon substrate 40 by, for example, sputtering or vapor deposition. The conductor that composes the seed layer 200 is, for example, but not limited to, copper (Cu). Further, since the diameter (outer dimension) D1 of the central conductor 110 is relatively large, the aspect ratio (hole depth/hole diameter) of the non-through hole 210 is small. Therefore, sputtering may reach a bottom part 210b of the non-through hole 210, whereby the seed layer 200 may be formed in the bottom part 210b as well.

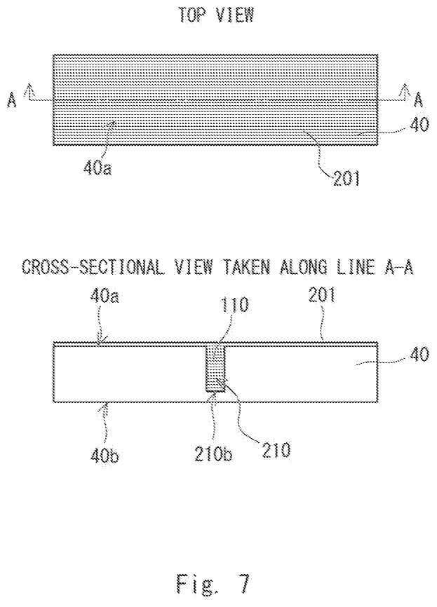

Next, as shown in FIG. 7, the seed layer 200 is connected to an electrode and a conductor film 201 such as a Cu film is formed by plating, whereby the non-through hole 210 is filled with the conductor. Accordingly, the central conductor 110 is formed. As described above, the seed layer 200 is also formed in the bottom part 210b of the non-through hole 210, whereby the central conductor 110 may be formed by plating so that it extends to the bottom part 210b of the non-through hole 210.

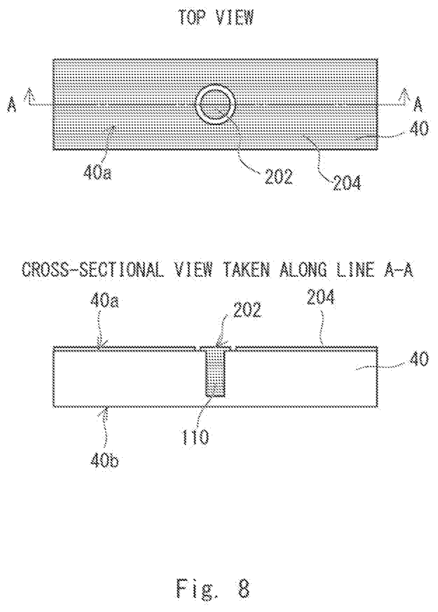

Next, as shown in FIG. 8, by performing, for example, a surface treatment such as etching on the conductor film 201, a pad 202 (central electrode; electrodes 42 and 44) for the central conductor 110, and a ground plane 204 (solid pattern) are formed. At this time, the pad 202 and the ground plane 204 are electrically insulated from each other by etching or the like. In this manner, the pad 202 of the central conductor 110 and the ground plane 204 can be easily formed.

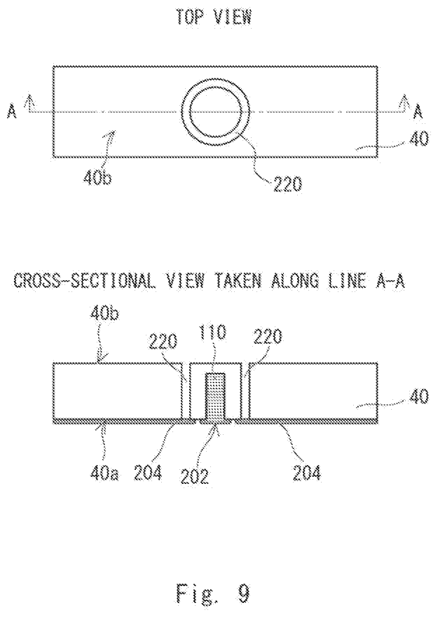

Next, as shown in FIG. 9, by turning over the silicon substrate 40 and performing a surface treatment such as etching on the rear surface 40b (the second surface) of the silicon substrate 40, a hole for an external conductor 220 (via), which is a hole for the external conductor 120, is formed around the central conductor 110. That is, a second surface, which is a surface opposite to the first surface of the silicon substrate 40, is subjected to a surface treatment, whereby the hole 220 for the external conductor is formed around the central conductor 110. In the first example embodiment, the hole 220 for the external conductor is formed so that it extends to the ground plane 204 formed on the front surface 40a.

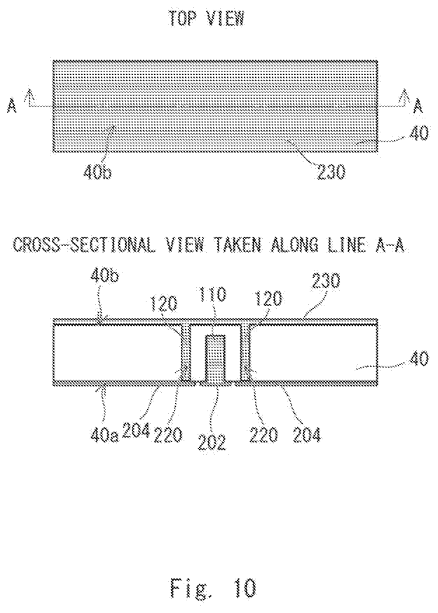

Next, as shown in FIG. 10, the ground plane 204 formed on the front surface 40a of the silicon substrate 40 is connected to an electrode, and a conductor film 230 such as a Cu film is formed on the rear surface 40b of the silicon substrate 40 by, for example, plating, whereby the hole 220 for the external conductor is filled with conductors such as Cu. Accordingly, the external conductor 120 is formed. As described above, the hole 220 for the external conductor is formed so that it extends to the ground plane 204, whereby the external conductor 120 can be formed by plating. Further, since the hole 220 for the external conductor is formed so that it extends to the ground plane 204, the external conductor 120 is electrically connected to the ground plane 204.

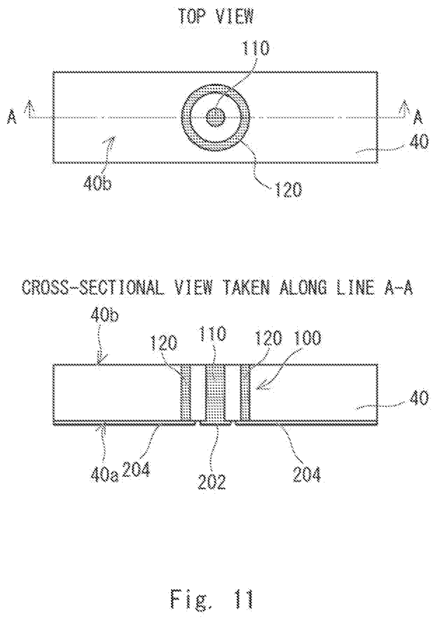

Next, as shown in FIG. 11, the rear surface 40b of the silicon substrate 40 is thinned. The rear surface 40b of the silicon substrate 40 may be thinned by, for example, polishing or grinding. Accordingly, the unnecessary conductor film 230 formed on the rear surface 40b is removed, and the central conductor 110 in the rear surface 40b is exposed. That is, the rear surface 40b (the second surface) is subjected to a surface treatment in such a way that the central conductor 110 is exposed in the rear surface 40b (the second surface). In this manner, the through electrode 100, which is a coaxial-type TSV, is formed in the silicon substrate 40. In a later process, a ground plane having a solid pattern that is similar to the ground plane 204, and a pad (central electrode) that is similar to the pad 202 may be formed on the rear surface 40b of the silicon substrate 40.

As described above, the through electrode 100 according to the first example embodiment includes the central conductor 110 that penetrates through the silicon substrate 40, and the external conductor 120 formed around the central conductor 110. Further, the central conductor 110 and the external conductor 120 are electrically insulated from each other by the silicon substrate 40 formed of a high-resistance silicon. Accordingly, the dielectric loss in the through electrode 100 can be reduced. Therefore, it is possible to keep a long coherence time of quantum computation in the superconducting circuit device 1.

Further, in the through electrode 100 according to the first example embodiment, the external conductor 120 is formed to have a tubular shape (it is not limited to a hollow cylinder) in such a way that the external conductor 120 surrounds the central conductor 110. In other words, the external conductor 120 according to the first example embodiment is formed to have a continuous ring shape (it is not limited to a circle) in the cross section of the silicon substrate 40 in a desired surface that is parallel to the front surface 40a (the first surface) of the silicon substrate 40. Accordingly, the central conductor 110 is completely surrounded by the external conductor 120, whereby it is possible to prevent leakage of electromagnetic waves from the central conductor 110, which is a core wire, and crosstalk more reliably.

Further, in order to form the external conductor 120 around the central conductor 110, in the aforementioned first example embodiment, after the central conductor 110 is formed from the front surface 40a of the silicon substrate 40, the hole 220 for the external conductor is formed in the rear surface 40b. Then, the hole 220 for the external conductor is filled with conductors by plating, whereby the external conductor 120 is formed. Specifically, when the central conductor 110 is formed from the front surface 40a of the silicon substrate 40, the ground plane 204 is formed on the front surface 40a by plating. Then, the hole 220 for the external conductor is formed from the rear surface 40b so that it extends to the ground plane 204 formed on the front surface 40a. Then, when the rear surface 40b is plated, the ground plane 204 formed on the front surface 40a is connected to the electrode.

Accordingly, it is possible to form the narrow external conductor 120 (that is, having a large aspect ratio) by plating. That is, the external conductor 120 can be formed in such a way that the width (W2) of the external conductor 120 becomes as large as 0.5 times or smaller than the outer dimension (D1) of the central conductor 110. Therefore, it is possible to form the through electrode 100 having the small outermost diameter D2 (outer dimension). That is, the hole 220 for the external conductor having a large aspect ratio is formed, and then the ground plane 204 formed on the front surface 40a, not the seed layer, is connected to the electrode, whereby the external conductor 120 having a large aspect ratio can be easily formed. In other words, the ground plane 204 provided in the bottom part of the hole 220 for the external conductor is connected to the electrode. Therefore, even when the aspect ratio of the hole 220 for the external conductor is large, the hole 220 for the external conductor can be definitely filled with conductors without gaps.

Further, when the rear surface 40b is plated, the ground plane 204 formed on the front surface 40a is connected to the electrode, which eliminates the need for the seed layer to be formed by sputtering when the external conductor 120 is formed. Now, consider a case in which a hole having a large aspect ratio is formed in order to form the external conductor 120 having a large aspect ratio, and the seed layer is formed in this hole by sputtering. In this case, it is possible that sputtering may not reach a deep part (e.g., the bottom part) of the hole as it is blocked by side walls in a shallow part of the hole. Therefore, it is possible that the seed layer may not be formed in the deep part of the hole having a large aspect ratio. In this case, even when the external conductor 120 is to be formed by plating, the seed layer is formed only in the shallow part of the hole. Therefore, the conductors can be formed only in the shallow part of the hole, and it is possible that the entire hole may not be filled with conductors. On the other hand, as described above, in the first example embodiment, there is no need to form the seed layer by sputtering when the external conductor 120 is formed, whereby the external conductor 120 having a large aspect ratio can be formed more reliably.

Further, as described above, in the first example embodiment, the front surface 40a (the first surface) of the silicon substrate 40 is subjected to a surface treatment, whereby the non-through hole 210 for the central conductor 110 is formed (FIG. 5). Then, by plating the front surface 40a, the non-through hole 210 is filled with conductors and the central conductor 110 is formed and the ground plane is formed on the front surface 40a (FIGS. 6-8). When the ground plane 204 is formed in this way, the ground plane 204 can be easily formed. That is, in the process of forming the central conductor 110, the ground plane 204 may be formed as well.

### Second Example Embodiment

Next, a second example embodiment will be described. In order to clarify the explanation, the following descriptions and the drawings are omitted and simplified as appropriate. Further, throughout the drawings, the same components are denoted by the same reference symbols, and overlapping descriptions are omitted as necessary. The second example embodiment is different from the first example embodiment in terms of the shape of the external conductor.

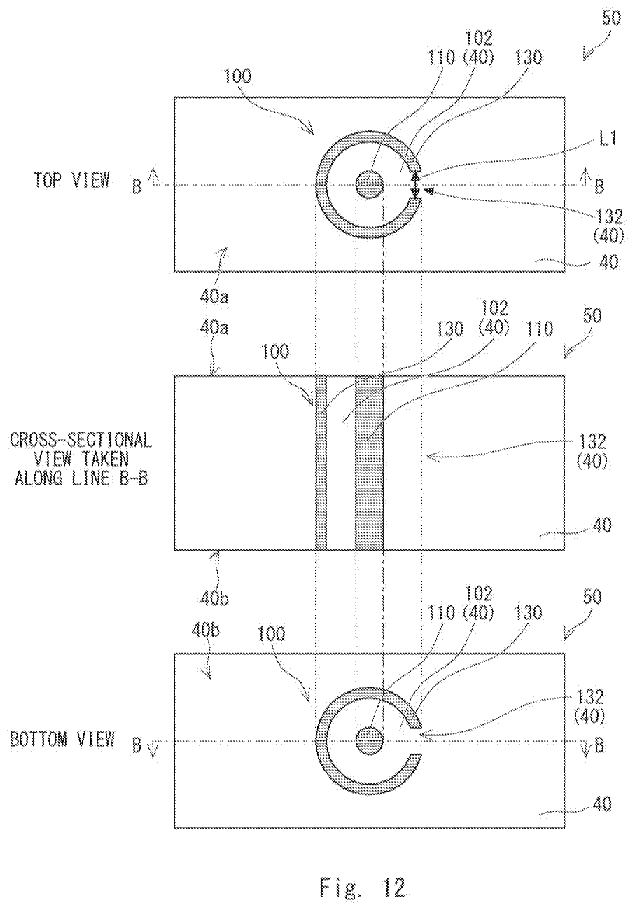

FIG. 12 is a view showing a wiring substrate 50 according to the second example embodiment. In FIG. 12, the top view (upper view) is a view of the wiring substrate 50 when it is viewed from the front surface 40a of the silicon substrate 40. The bottom view (lower view) is a view of the wiring substrate 50 when it is viewed from the rear surface 40b of the silicon substrate 40. Further, the cross-sectional view (middle view) is a view of the cross section taken along the line B-B in the top view and the bottom view (the same is applied to the figures described below).

The wiring substrate 50 according to the second example embodiment includes a silicon substrate 40 formed of a high-resistance silicon, and a through electrode 100, which is, for example, a coaxial-type TSV. The through electrode 100 includes a central conductor 110 that penetrates through the silicon substrate 40, and an external conductor 130. The external conductor 130 corresponds to the external conductor 120 according to the first example embodiment. Like the external conductor 120 according to the first example embodiment, the external conductor 130 is formed around the central conductor 110. An insulating layer 102 is provided between the central conductor 110 and the external conductor 130 by the silicon substrate 40. That is, the central conductor 110 and the external conductor 130 are electrically insulated from each other by the silicon substrate 40.

In the second example embodiment as well, the central conductor 110 is formed, for example, in a columnar shape such as a cylindrical shape. Further, the external conductor 130 according to the second example embodiment is formed to have an annular shape (ring shape) in such a way that a part of it in the cross section in a desired surface that is parallel to the front surface 40a of the silicon substrate 40 is cut out. That is, the external conductor 130 according to the second example embodiment is formed in such a way that a part of the annular shape (ring shape) is missing in the cross section in a desired surface that is parallel to the front surface 40a of the silicon substrate 40. In other words, the external conductor 130 according to the second example embodiment is not in a continuous ring shape in the cross section in a desired surface that is parallel to the front surface 40a of the silicon substrate 40. In other words, the external conductor 130 according to the second example embodiment is formed to have a C shape in the cross section in a desired surface that is parallel to the front surface 40a of the silicon substrate 40. That is, the external conductor 130 according to the second example embodiment is formed to have a C shape when it is viewed from the front surface 40a of the silicon substrate 40. In other words, the external conductor 130 according to the second example embodiment is formed to surround the central conductor 110 in such a way that the external conductor 130 has a ring shape in which a part of it is cut out. In other words, the external conductor 130 according to the second example embodiment is formed to have a ring shape in such a way that a part of it is cut out when it is viewed from the front surface 40a (or the rear surface 40b). In other words, the external conductor 130 according to the second example embodiment is formed around the central conductor 110 in such a way that the external conductor 130 has a ring shape in which a part of the external conductor 130 that circles around the central conductor 110 is cut out.

That is, the external conductor 130 according to the second example embodiment includes a cutout part 132 on its side surface thereof. Then, this cutout part 132 is formed of the silicon substrate 40. Accordingly, the external conductor 130 according to the second example embodiment is formed to have a hollow cylinder shape (tubular shape) in which a groove (cutout part 132) is formed on the side surface of the external conductor 130. Therefore, the external conductor 130 according to the second example embodiment is formed in such a way that the cross-sectional shape in a desired surface that is parallel to the front surface 40a of the silicon substrate 40 becomes the same (C shape) regardless of the position (that is, cutoff position) of the thickness direction of the silicon substrate 40. In other words, the external conductor 120 according to the first example embodiment is formed in such a way that it has a continuous shape (C shape) in the thickness direction of the silicon substrate 40. The reason why the cross section of the external conductor 130 according to the second example embodiment is formed to have a C shape as described above will be described later.

Like the external conductor 120 according to the first example embodiment, in the second example embodiment, the external conductor 120 is formed in such a way that the cross-sectional shape in a desired surface that is parallel to the front surface 40a of the silicon substrate 40 becomes the same regardless of the position of the silicon substrate 40 in the thickness direction. Therefore, the wiring substrate 50 (the through electrode 100) according to the second example embodiment may be manufactured in a method that is substantially the same as the manufacturing method according to the first example embodiment.

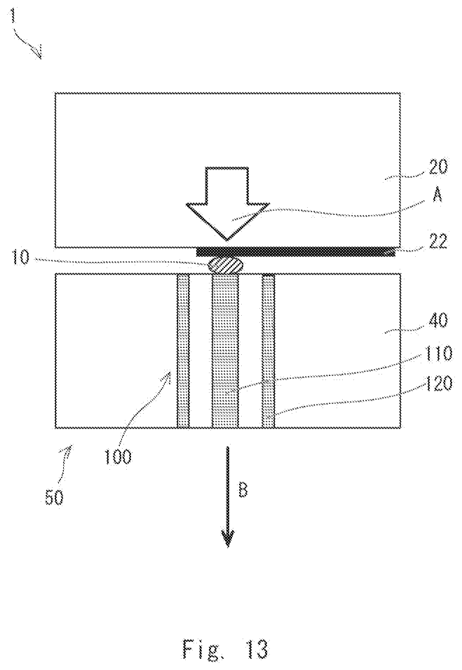

FIGS. 13-16 are views for describing effects of forming the external conductor 130 according to the second example embodiment in the shape as shown in FIG. 12. In general, the coupling (degree of adhesion) between the conductor (central conductor 110) formed by plating and the silicon substrate 40 is weak. Therefore, if a pressure is applied to the central conductor 110, it is possible that the central conductor 110 may be removed from the silicon substrate 40.

FIG. 13 is a view for describing a problem when the quantum circuit chip 20 is flip-chip connected to the silicon substrate 40 in which the through electrode 100 according to the first example embodiment is formed. When the quantum circuit chip 20 is flip-chip connected to the silicon substrate 40 in which the through electrode 100 according to the first example embodiment is formed, a pressure is applied to the central conductor 110 of the through electrode 100 via the bump 10 in a direction shown by an arrow A. Accordingly, as shown by an arrow B, it is possible that the through electrode 100 (central conductor 110) may be removed from the silicon substrate 40 and thus the through electrode 100 may be damaged.

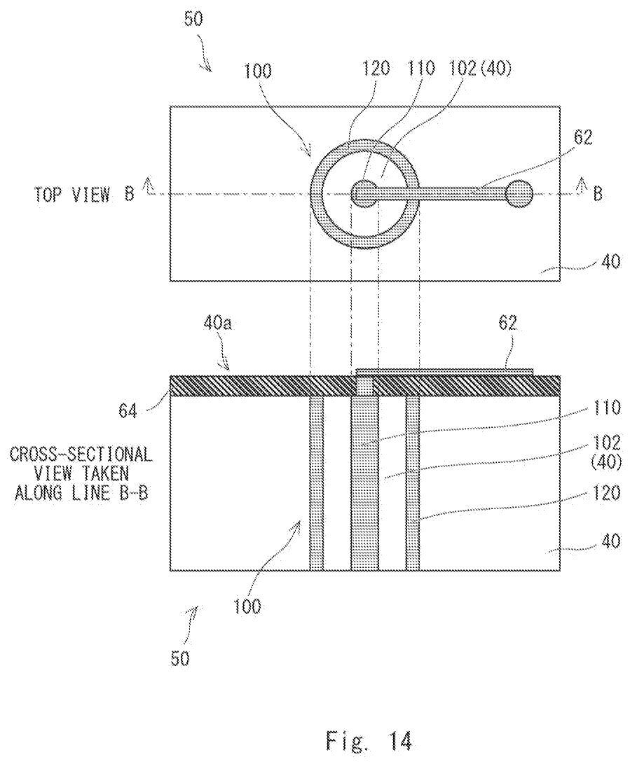

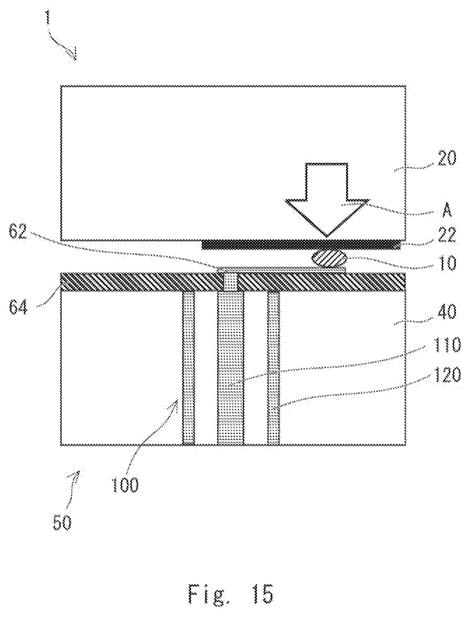

FIGS. 14 and 15 are views for describing an example of a method of alleviating the problem described with reference to FIG. 13. As shown in FIG. 14, a lead-out line 62 is connected to the central conductor 110. In order to electrically insulate the lead-out line 62 from the external conductor 120, an insulating layer 64 is provided on the front surface 40a (or the rear surface 40b) of the silicon substrate 40.

Accordingly, as shown in FIG. 15, the position of the bump 10 may be shifted from a part just above the central conductor 110. Therefore, it is possible to prevent a pressure from being applied to the central conductor 110 and prevent the central conductor 110 from being removed from the silicon substrate 40 when the bump 10 is pressed in the direction shown by the arrow A at the time of flip-chip connection. Further, the quantum circuit 22 and the central conductor 110 are electrically connected to each other by the lead-out line 62.

However, in this example, in order to electrically insulate the lead-out line 62 from the external conductor 120, the insulating layer 64 needs to be formed on the front surface 40a. This insulating layer 64 may be made of, for example, SiO₂. However, as described above, since the dielectric loss of the insulating material such as SiO₂ is large, there is a problem that the coherence time of the quantum circuit 22 may be reduced.

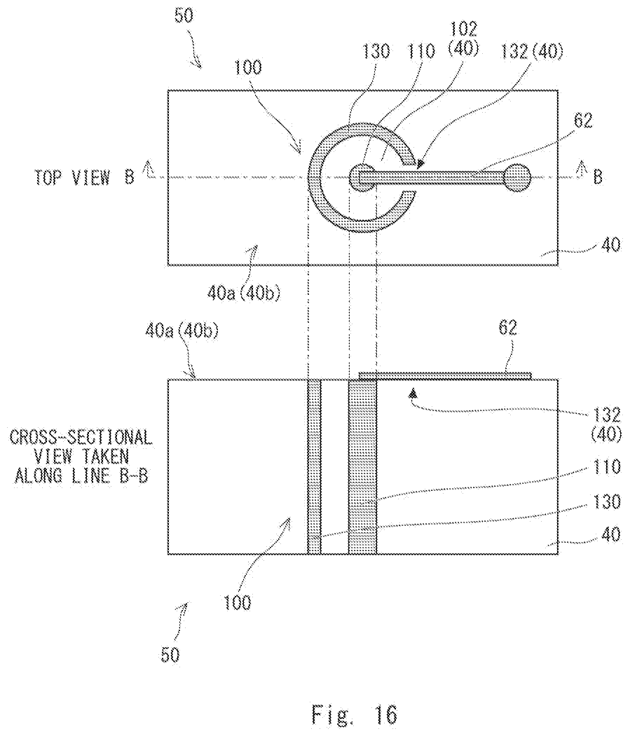

FIG. 16 is a view showing a state in which the lead-out line 62 is connected to the through electrode 100 according to the second example embodiment. In the through electrode 100 according to the second example embodiment, as shown in FIG. 16, the lead-out line 62 is connected to the central conductor 110. At this time, the lead-out line 62 is disposed in the cutout part 132 in the front surface 40a or the rear surface 40b. Accordingly, even when the insulating layer is not formed in the front surface 40a or the rear surface 40b, the lead-out line 62 and the external conductor 130 can be electrically insulated from each other. Therefore, it is possible to prevent the through electrode 100 from being damaged while preventing the coherence time of the quantum circuit 22 from being reduced. That is, by using the through electrode 100 according to the second example embodiment, it is possible to increase the mechanical strength of the through electrode 100 while preventing the coherence time of the quantum circuit 22 from being reduced.

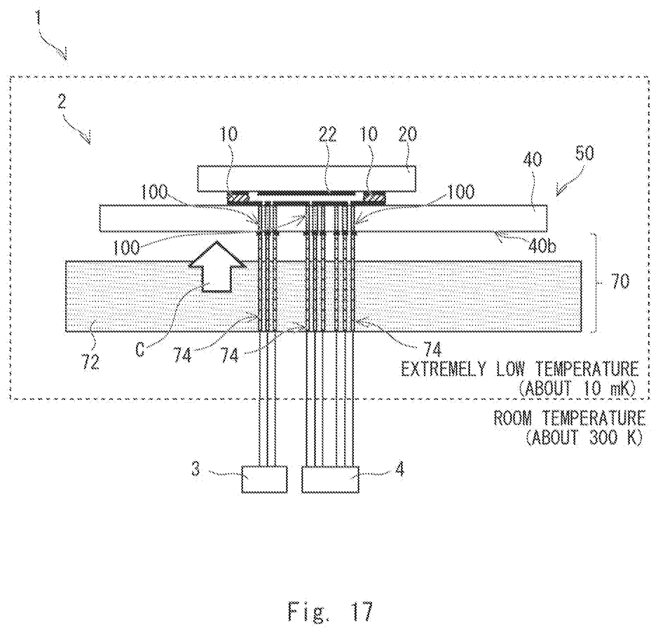

FIGS. 17-19 are views for describing an implementation example of the through electrodes 100 according to the second example embodiment. In the implementation example shown in FIG. 17, the superconducting circuit device 1 includes the wiring substrate 50, and the readout unit 3 and the control unit 4 that are connected to each other via a socket 70. Specifically, after the silicon substrate 40 is mounted on the socket 70, the readout unit 3 and the control unit 4 are connected to the socket 70. Incidentally, the socket 70 is formed of a housing 72 made of ceramic on which a number of probe pins 74 made of metal are mounted. These probe pins 74 are bonded under pressure to the through electrodes 100, whereby the probe pins 74 and the through electrodes 100 are electrically connected to each other.

At this time, a pressure is applied to the through electrodes 100 from the probe pins 74. Therefore, it is possible that the damage such as removal (falling off) stated above may occur in the through electrodes 100. Further, since the coefficient of linear expansion of Cu is larger than the coefficient of linear expansion of Si, if the superconducting quantum computer is cooled down to an extremely low temperature of about 10 mK from room temperature, Cu is contracted more strongly than Si is. Here, since the difference between room temperature and the extremely low temperature (e.g., 10 mK) is as large as about 300 degrees, the impact of the difference of this contraction is large. As a result, the degree of adhesion between Cu (conductor) and Si (silicon substrate 40) of the through electrodes 100 is further reduced, which increases the possibility that the through electrodes 100 are damaged. This is a problem specific to a superconducting quantum computer that is cooled down to an extremely low temperature.

In order to avoid the above damage, it may be possible to employ a method of shifting the position of the rear surface 40b of the silicon substrate 40 that the probe pins 74 hit from the conductor (central conductor 110) by the lead-out line 62. As described above, the second example embodiment is advantageous over the first example embodiment since the insulating layer is not necessary in the second example embodiment while the insulating layer needs to be formed in the silicon substrate 40 in the first example embodiment.

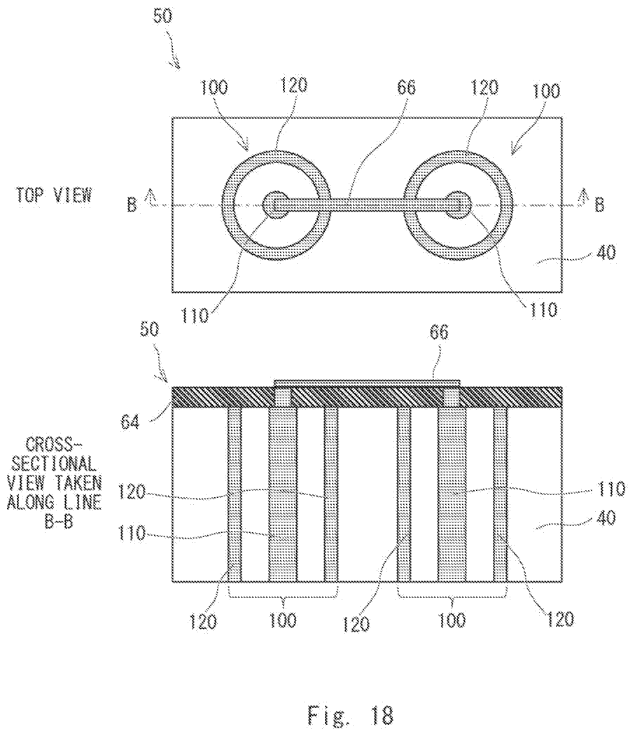

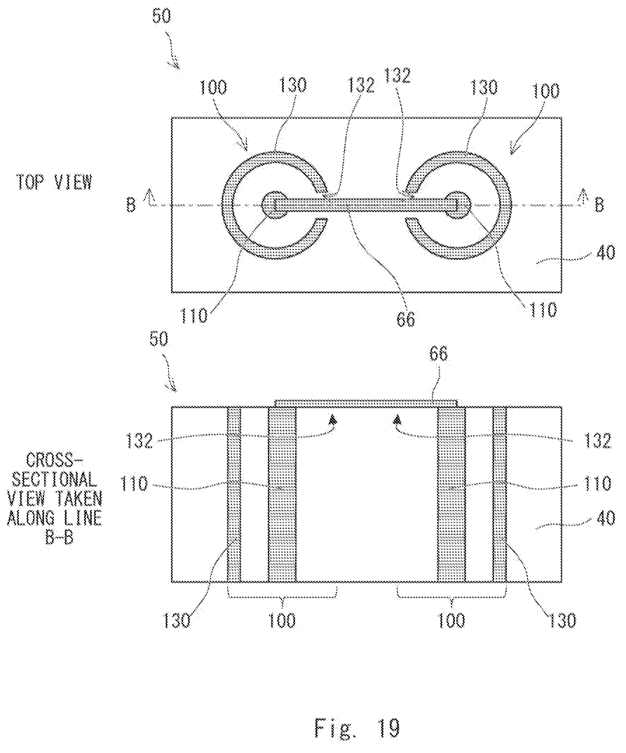

FIGS. 18 and 19 are views showing implementation examples in which two through electrodes 100 are connected to each other by a wire. FIGS. 18 and 19 each show an inductor (wire) for controlling the quantum circuit 22. Various wires are connected to the central conductors 110 (core wires) of the through electrodes 100. FIG. 18 is a view showing a state in which the central conductors 110 of the two through electrodes 100 according to the first example embodiment are connected to each other via a wire 66. In this case, in order to electrically insulate the wire 66 from the external conductors 120, the insulating layer 64 needs to be formed in the silicon substrate 40. However, as described above, since the insulating material has a large dielectric loss, there is a problem that the coherence time of the quantum circuit 22 may be reduced.

On the other hand, FIG. 19 is a view showing a state in which the central conductors 110 of the two through electrodes 100 according to the second example embodiment are connected to each other by the wire 66. In this case, the wire 66 is disposed in the cutout parts 132. Accordingly, even when the insulating layer is not formed in the silicon substrate 40, the wire 66 and the external conductors 130 can be electrically insulated from each other. Therefore, it is possible to prevent the coherence time of the quantum circuit 22 from being reduced. That is, by using the through electrodes 100 according to the second example embodiment, it is possible to provide wires of a variety of layouts while preventing the coherence time of the quantum circuit 22 from being reduced.

In the second example embodiment, the length L1 of the cutout part 132 (FIG. 12) is preferably not too large in view of high-frequency characteristics. If the length L1 (separation distance) of the cutout part 132 is too long, it becomes difficult to prevent electromagnetic leakage and crosstalk related to the leakage. On the other hand, if the length L1 of the cutout part 132 is too short, it becomes difficult to connect the lead-out line 62 and the wire 66 to the central conductors 110 so as to insulate the lead-out line 62 and the wire 66 from the external conductor 130. Therefore, the length L1 of the cutout part 132 is preferably larger than the width of the lead-out line 62 and the wire 66 and is equal to or smaller than the diameter D1 of the central conductor 110. That is, the separation distance L1 of a part where the external conductor 130 is cut out is preferably equal to or smaller than the diameter of the central conductor 110. When, for example, the width of the lead-out line 62 and the wire 66 is 1 μm and D1 is 50 μm, L1 is preferably 2 μm or larger but 50 μm or smaller, considering that the impedance needs to be as low as about 50Ω.

### Third Example Embodiment

Next, a third example embodiment will be described. In order to clarify the explanation, the following descriptions and the drawings are omitted and simplified as appropriate. Further, throughout the drawings, the same components are denoted by the same reference symbols, and overlapping descriptions are omitted as necessary. The third example embodiment is different from the first and second example embodiments as the shape of the external conductor according to the third example embodiment is different from those in the first and second example embodiments.

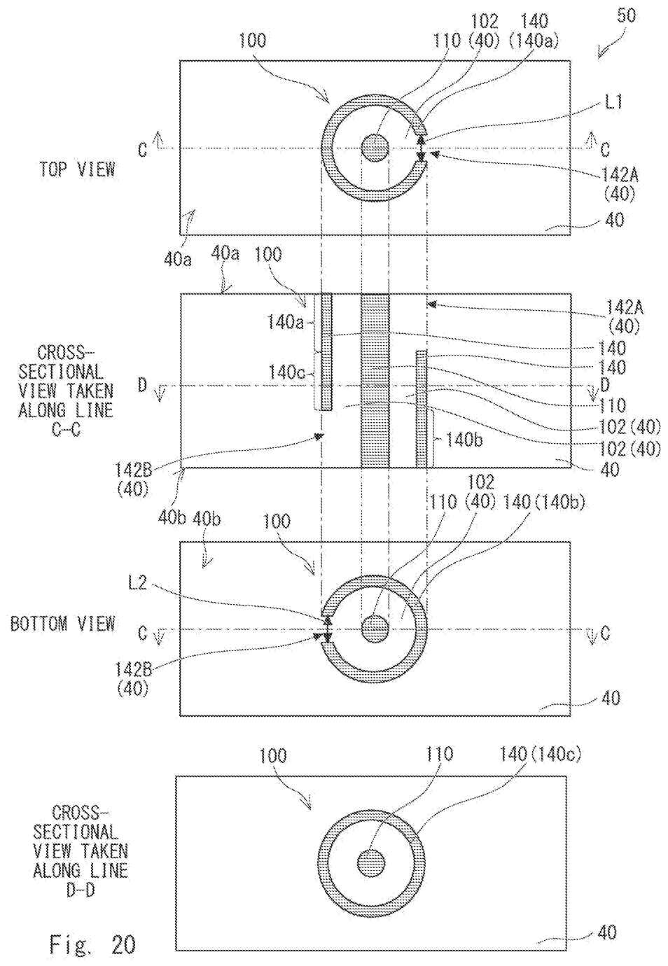

FIG. 20 is a view showing a wiring substrate 50 according to the third example embodiment. In FIG. 20, the top view (figure shown at the top) is a view of the wiring substrate 50 when it is viewed from the front surface 40a of the silicon substrate 40. The bottom view (the second figure from the bottom) is a view of the wiring substrate 50 when it is viewed from the rear surface 40b of the silicon substrate 40. Further, the cross-sectional view (the second figure from the top) shows the cross section taken along the line C-C in the top view and the bottom view (the same is applied to the figures described below). Further, the cross-sectional view (the figure shown at the bottom) shows the cross section taken along the line D-D in the cross-sectional view taken along the line C-C (the second figure from the top).

The wiring substrate 50 according to the third example embodiment includes a silicon substrate 40 formed of a high-resistance silicon, and a through electrode 100, which is, for example, a coaxial-type TSV. The through electrode 100 includes a central conductor 110 that penetrates through the silicon substrate 40, and an external conductor 140. The external conductor 140 corresponds to the external conductor 120 according to the first example embodiment. Like the external conductor 120 according to the first example embodiment, the external conductor 140 is formed around the central conductor 110. An insulating layer 102 is provided between the central conductor 110 and the external conductor 140 by the silicon substrate 40. That is, the central conductor 110 and the external conductor 140 are electrically insulated from each other by the silicon substrate 40.

In the third example embodiment as well, the central conductor 110 is formed to have a columnar shape such as a cylindrical shape. Further, the external conductor 140 according to the third example embodiment includes an external conductor part 140a (a first external conductor part) formed on the side of the front surface 40a of the silicon substrate 40, and an external conductor part 140b (a second external conductor part) formed on the side of the rear surface 40b of the silicon substrate 40. Therefore, the external conductor part 140a does not penetrate through the silicon substrate 40. Likewise, the external conductor part 140b does not penetrate through the silicon substrate 40.

As shown in FIG. 20, the external conductor 140 may include an external conductor part 140c (a third external conductor part) between the external conductor part 140a and the external conductor part 140b. In this case, the external conductor part 140a and the external conductor part 140b are electrically connected to each other via the external conductor part 140c. As shown in the cross-sectional view taken along the line D-D, the external conductor part 140c is formed to have a hollow cylinder shape (tubular shape) that does not include a groove on its side surface, like in the external conductor 120 according to the first example embodiment. That is, the external conductor part 140c is formed to have a continuous ring shape in the cross section of the silicon substrate 40 in a desired surface that is parallel to the front surface 40a of the silicon substrate 40. In other words, the external conductor part 140c is formed to surround the central conductor 110 in such a way that the external conductor part 140c is formed to have a continuous ring shape. In other words, the external conductor part 140c is formed to have a continuous ring shape when it is viewed from the front surface 40a (or the rear surface 40b). In other words, the external conductor part 140c is formed around the central conductor 110 in such a way that the external conductor part 140c has a continuous ring shape that circles around the central conductor 110.

Alternatively, the external conductor 140 may not include the external conductor part 140c between the external conductor part 140a and the external conductor part 140b. In this case, the external conductor part 140a and the external conductor part 140b may be electrically connected to each other as a result of direct physical coupling between them. That is, regardless of whether the external conductor part 140c is provided or not, the external conductor part 140a and the external conductor part 140b are electrically connected to each other. Therefore, like in the aforementioned example embodiments, in the external conductor 140, the side of the front surface 40a of the silicon substrate 40 and the side of the rear surface 40b of the silicon substrate 40 can be electrically conducted definitely.

Further, like the external conductor 130 according to the second example embodiment, the external conductor part 140a according to the third example embodiment is formed to have an annular shape (ring shape) in such a way that a part of the external conductor part 140a in the cross section in a surface that is parallel to the front surface 40a of the silicon substrate 40 is cut out. Therefore, the external conductor part 140a according to the third example embodiment includes a cutout part 142A (a first cutout part) on its side surface. In other words, the external conductor part 140a according to the third example embodiment is formed to have a C shape in the cross section in a desired surface that is parallel to the front surface 40a of the silicon substrate 40. That is, the external conductor part 140a according to the third example embodiment is formed so as to have a C shape when it is viewed from the front surface 40a of the silicon substrate 40. Likewise, the external conductor part 140b according to the third example embodiment is formed to have an annular shape (ring shape) in which a part of the external conductor part 140b in the cross section in a surface that is parallel to the rear surface 40b of the silicon substrate 40 is cut out. Therefore, the external conductor part 140b according to the third example embodiment includes a cutout part 142B (a second cutout part) on its side surface. In other words, the external conductor part 140b according to the third example embodiment is formed to have a C shape in the cross section in a desired surface that is parallel to the rear surface 40b of the silicon substrate 40. That is, the external conductor part 140b according to the third example embodiment is formed to have a C shape when it is viewed from the rear surface 40b of the silicon substrate 40. Then, these cutout parts 142A and 142B are formed of the silicon substrate 40. Accordingly, the external conductor parts 140a and 140b according to the third example embodiment are formed to have a hollow cylinder shape (tubular shape) in which a groove is formed on its side surface. In other words, the external conductor 140 is formed to have a tubular shape in which a groove (cutout part) is formed on its side surface on the side of the front surface 40a and the side of the rear surface 40b of the silicon substrate 40. Further, in other words, the external conductor parts 140a and 140b according to the third example embodiment are formed to surround the central conductor 110 in such a way that the external conductor parts 140a and 140b are formed to have a continuous ring shape. In other words, the external conductor parts 140a and 140b according to the third example embodiment are formed to have a continuous ring shape when they are viewed from the front surface 40a (or the rear surface 40b). Further, in other words, the external conductor parts 140a and 140b according to the third example embodiment are formed around the central conductor 110 in such a way that the external conductor parts 140a and 140b have a continuous ring shape that circles around the central conductor 110.

The position (first position) of the cutout part 142A in the external conductor part 140a does not necessarily correspond to the position (second position) of the cutout part 142B in the external conductor part 140b. In FIG. 20, the cutout part 142A in the external conductor part 140a is provided on the right side of the central conductor 110 and the cutout part 142B in the external conductor part 140b is provided on the left side of the central conductor 110. In other words, when the wiring substrate 50 is viewed from the front surface 40a, the position (first position) of the cutout part 142A in the external conductor part 140a formed on the side of the front surface 40a is different from the position (second position) of the cutout part 142B in the external conductor part 140b formed on the side of the rear surface 40b. In other words, the orientation of the position of the cutout part 142A in the front surface 40a with respect to the central conductor 110 is different from the orientation of the position of the cutout part 142B in the rear surface 40b with respect to the central conductor 110. That is, the first position with respect to the central conductor 110 is different from the second position with respect to the central conductor 110.

The reason why the external conductor 140 according to the third example embodiment is formed as described above will be described below. In the structure according to the second example embodiment shown in FIG. 12, the position of the cutout part 132 in the front surface 40a of the silicon substrate 40 corresponds to the position of the cutout part 132 in the rear surface 40b of the silicon substrate 40 when the wiring substrate 50 is viewed from the front surface 40a of the silicon substrate 40. That is, the orientation of the position of the cutout part 132 in the front surface 40a with respect to the central conductor 110 is the same as the orientation of the position of the cutout part 132 in the rear surface 40b with respect to the central conductor 110. Therefore, in the structure according to the second example embodiment, there is a restriction that the direction of the wire drawn from the central conductor 110 in the front surface 40a of the silicon substrate 40 must be the same as the direction of the wire drawn from the central conductor 110 in the rear surface 40b of the silicon substrate 40.

On the other hand, in the structure according to the third example embodiment, the orientation of the position of the cutout part 142A in the front surface 40a with respect to the central conductor 110 is different from the orientation of the position of the cutout part 142B in the rear surface 40b with respect to the central conductor 110. Therefore, by employing the structure according to the third example embodiment, the direction of the wire drawn from the central conductor 110 can be changed to a desired direction, as will be described later. Therefore, the flexibility in wiring design is increased.

Like the cutout part 132 according to the second example embodiment, when high-frequency signals are transmitted, in view of prevention of electromagnetic leakage and crosstalk related to the leakage, the length L1 of the cutout part 142A and the length L2 of the cutout part 142B are preferably not very long. That is, the length L1 of the cutout part 142A and the length L2 of the cutout part 142B are preferably longer than the width of the wire and equal to or smaller than the diameter D1 of the central conductor 110. When, for example, the width of the wire is 1 μm and D1 is 50 μm, L1 and L2 are preferably 2 μm or larger but 50 μm or smaller, considering that the impedance needs to be as low as about 50Ω.

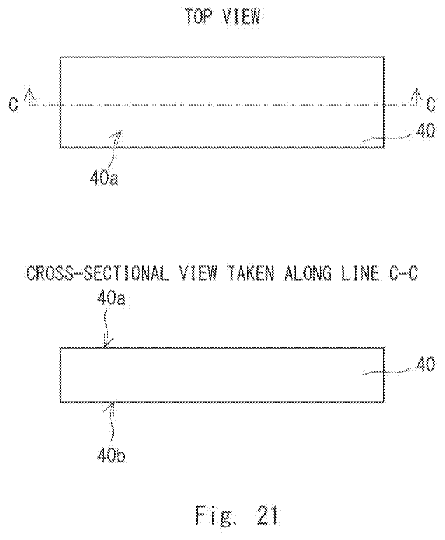

FIGS. 21-30 are views showing a method of manufacturing the wiring substrate 50 according to the third example embodiment. In FIGS. 21-30, upper views show top views and lower views show cross-sectional views. The top views are views of the silicon substrate 40 when it is viewed from the front surface 40a of the silicon substrate 40 or from the rear surface 40b when the silicon substrate 40 is turned over.

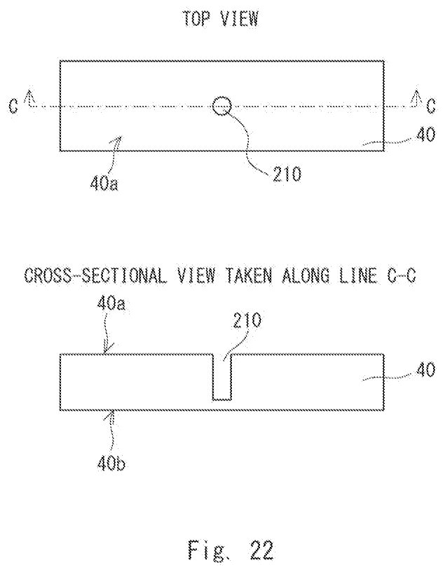

First, as shown in FIG. 21, the silicon substrate 40 is prepared. Next, as shown in FIG. 22, a non-through hole 210 (blind via) for the central conductor 110 is formed in the front surface 40a of the silicon substrate 40 by, for example, a surface treatment such as etching. That is, the front surface 40a (the first surface) of the silicon substrate 40 is subjected to a surface treatment, whereby the non-through hole 210 for the central conductor 110 is formed.

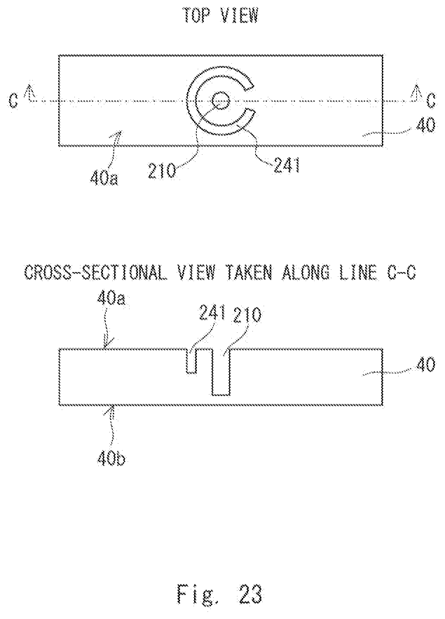

Next, as shown in FIG. 23, by performing a surface treatment such as etching on the front surface 40a of the silicon substrate 40, a hole 241 for an external conductor (a first hole for the external conductor) for the external conductor 140 (external conductor part 140a) is formed around the central conductor 110. The hole 241 for the external conductor is formed in such a way that the shape thereof in a surface parallel to the front surface 40a of the silicon substrate 40 becomes a C shape. That is, the hole 241 for the external conductor is formed so as to be a C shape when it is viewed from the front surface 40a of the silicon substrate 40. Further, the surface treatment is performed in such a way that the hole 241 for the external conductor becomes shallower than the non-through hole 210 for the central conductor 110. That is, the hole 241 for the external conductor is a non-through hole (blind via).

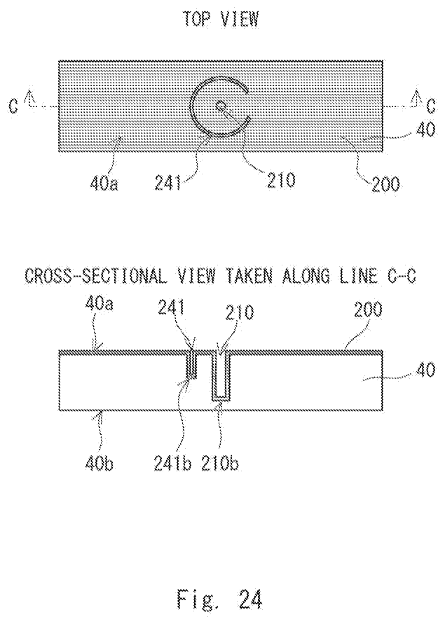

Next, as shown in FIG. 24, a seed layer 200 (a first seed layer) of a conductor (e.g., Cu) is formed across the entire front surface 40a of the silicon substrate 40 by, for example, sputtering. As described above, since the aspect ratio (hole depth/hole diameter) of the non-through hole 210 is small, sputtering may reach a bottom part 210b of the non-through hole 210. Therefore, the seed layer 200 may be formed in the bottom part 210b as well. Further, the width of the hole 241 for the external conductor is narrower than the diameter of the non-through hole 210 but the hole 241 for the external conductor is shallower than the non-through hole 210. Therefore, the aspect ratio of the hole 241 for the external conductor is small enough that sputtering may reach the bottom part 241b of the hole 241 for the external conductor. Therefore, the seed layer 200 may be formed in the bottom part 241b as well.

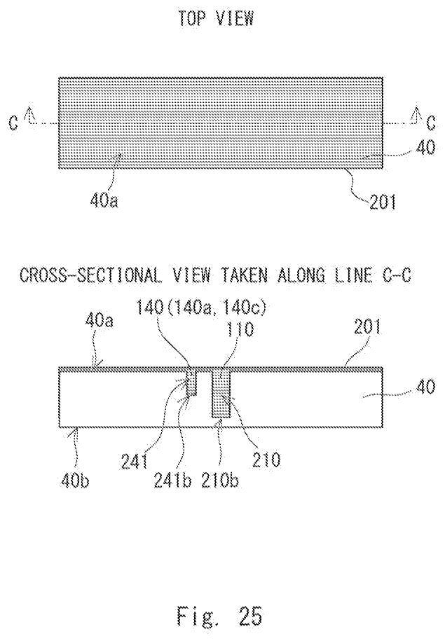

Next, as shown in FIG. 25, the seed layer 200 is connected to an electrode and the seed layer 200 is plated. A conductor film 201 such as a Cu film is formed by plating, whereby the non-through hole 210 and the hole 241 for the external conductor are filled with conductors. Accordingly, a part of the central conductor 110 and the external conductor 140 (external conductor parts 140a and 140c) is formed. As described above, since the seed layer 200 is formed also in the bottom part 210b of the non-through hole 210, the central conductor 110 can be formed by plating. Likewise, the seed layer 200 is formed also in the bottom part 241b of the hole 241 for the external conductor, whereby the external conductor part 140a (and the external conductor part 140c) can be formed by plating.

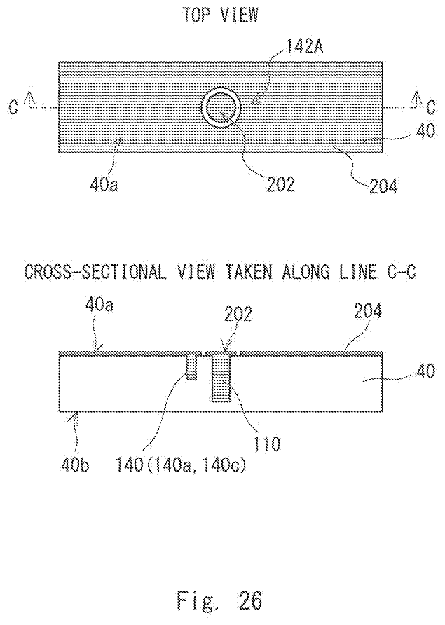

Next, as shown in FIG. 26, the conductor film 201 is subjected to a surface treatment such as etching, whereby the pad 202 (central electrode; electrodes 42 and 44) for the central conductor 110, and the ground plane 204 (solid pattern) are formed. At this time, the pad 202 and the ground plane 204 are electrically insulated from each other by etching or the like. In this manner, the pad 202 of the central conductor 110 and the ground plane 204 can be easily formed. The external conductor part 140a is electrically connected to the ground plane 204. When the aforementioned wire that is connected to the central conductor 110 and is insulated from the external conductor 140 is formed, the conductor in the part of the ground plane 204 that corresponds to the cutout part 142A may be removed by etching or the like.

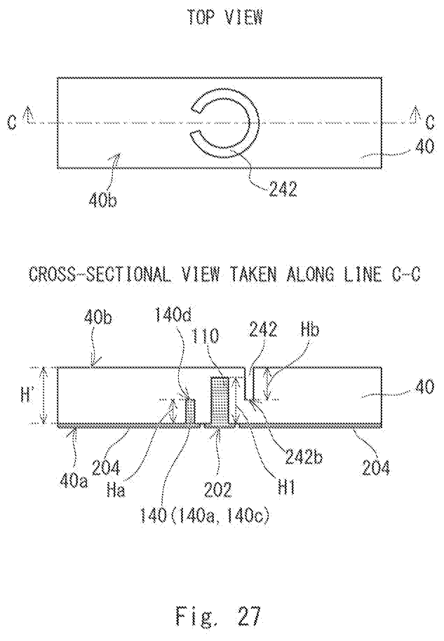

Next, as shown in FIG. 27, the silicon substrate 40 is turned over. Then, the rear surface 40b (the second surface) of the silicon substrate 40 is subjected to a surface treatment such as etching, whereby a hole 242 for an external conductor (a second hole for the external conductor), which is a hole for the external conductor 140 (external conductor part 140b), is formed around the central conductor 110. That is, by performing the treatment on the second surface, which is a surface opposite to the first surface of the silicon substrate 40, the hole 242 for the external conductor is formed around the central conductor 110.

The hole 242 for the external conductor is formed in such a way that the shape in a surface that is parallel to the rear surface 40b of the silicon substrate 40 becomes a C shape. That is, the hole 242 for the external conductor is formed to have a C shape when it is viewed from the rear surface 40b of the silicon substrate 40. Further, the surface treatment is performed in such a way that the hole 242 for the external conductor becomes shallower than the non-through hole 210 for the central conductor 110. That is, the hole 242 for the external conductor is a non-through hole (blind via). Further, the surface treatment is performed in such a way that the bottom part 242b of the hole 242 for the external conductor becomes deep enough so that it reaches at least the bottom part 140d of the external conductor 140 (external conductor parts 140a and 140c) formed in the process shown in FIG. 26. That is, in the state shown in FIG. 27, the thickness of the silicon substrate 40 is denoted by H′. Further, the height (depth) of the central conductor 110 is denote by H1, the height of the external conductor 140 (external conductor parts 140a and 140c) formed in the process shown in FIG. 26 is denoted by Ha, and the depth of the hole 242 for the external conductor is denoted by Hb. In this case, the following Expression 1 is established.

(H′−Ha)≤Hb<H1 (1)

That is, the total of the depth Ha of the hole 241 for the external conductor (a first hole for the external conductor) and the depth Hb of the hole 242 for the external conductor (a second hole for the external conductor) is equal to or larger than the thickness H′ of the silicon substrate 40.

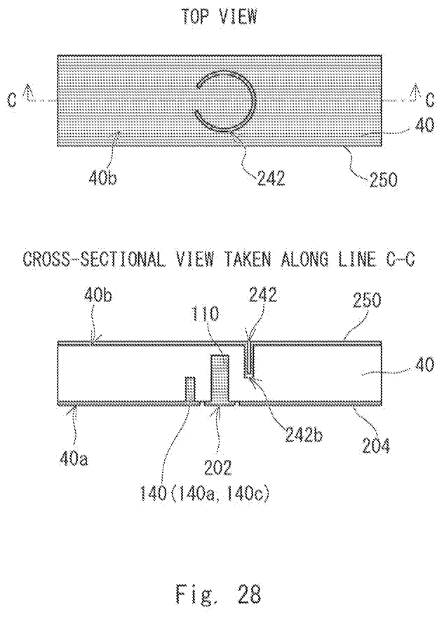

Next, as shown in FIG. 28, a seed layer 250 (a second seed layer) such as a conductor (e.g., Cu) is formed across the entire rear surface 40b of the silicon substrate 40 by, for example, sputtering. While the width of the hole 242 for the external conductor is narrower than the diameter of the non-through hole 210, the hole 242 for the external conductor is shallower than the non-through hole 210. Therefore, the aspect ratio of the hole 242 for the external conductor is sufficiently small so that sputtering may reach the bottom part 242b of the hole 242 for the external conductor. Therefore, the seed layer 250 may be formed in the bottom part 242b as well.

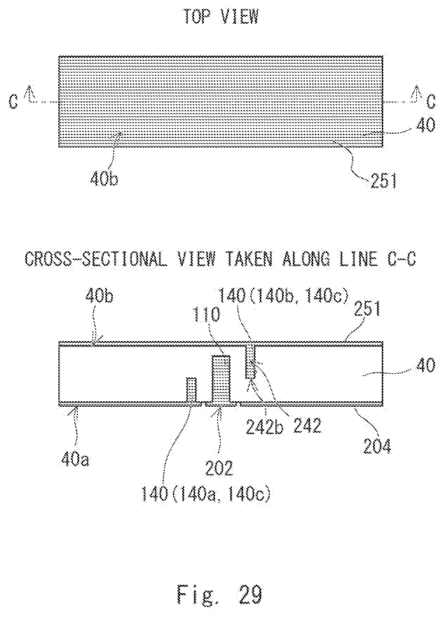

Next, as shown in FIG. 29, the seed layer 250 is connected to an electrode and the seed layer 250 is plated. A conductor film 251 such as a Cu film is formed by plating, whereby the hole 242 for the external conductor is filled with conductors. Accordingly, a part of the external conductor 140 (external conductor parts 140b and 140c) is formed. As described above, since the seed layer 250 is formed also in the bottom part 242b of the hole 242 for the external conductor, it is possible to form the external conductor part 140b (and the external conductor part 140c) by plating.

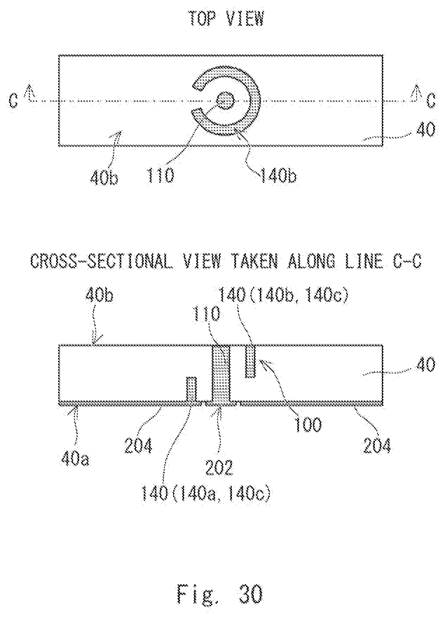

Next, like in the process shown in FIG. 11, as shown in FIG. 30, the rear surface 40b of the silicon substrate 40 is thinned. The rear surface 40b may be thinned, for example, by polishing or grinding. Accordingly, the unnecessary conductor film 251 that has been formed on the rear surface 40b is removed, and further the central conductor 110 and the external conductor part 140b in the rear surface 40b are exposed. That is, the rear surface 40b (the second surface) is subjected to a surface treatment in such a way that the central conductor 110 and the external conductor part 140b are exposed in the rear surface 40b (the second surface). In this manner, the through electrodes 100, which are coaxial-type TSVs, are formed in the silicon substrate 40. In a later process, a ground plane having a solid pattern similar to the ground plane 204, and a pad (central electrode) that is similar to the pad 202 may be formed on the rear surface 40b of the silicon substrate 40.

If (H−Ha)=Hb is established in the above Expression 1, the external conductor part 140c is not formed between the external conductor part 140a and the external conductor part 140b. Therefore, in this case, the external conductor part 140a and the external conductor part 140b are physically coupled to each other directly.

As regards the transmission of high-frequency signals, the external conductor part 140c formed to have a continuous ring shape is preferably provided. Then, the height of the external conductor part 140c (the length of the silicon substrate 40 in the thickness direction) is preferably made large. If the height of the external conductor part 140c is to be increased, the holes 241 and 242 for the external conductors need to be deepened. However, if the holes 241 and 242 for the external conductors are deepened, it is highly likely that sputtering may not reach the bottom parts of the holes 241 and 242 for the external conductors at the time of sputtering. Therefore, the holes 241 and 242 for the external conductors are preferably deepened to the extent that sputtering reaches the bottom parts.

In FIG. 20, when the wiring substrate 50 is viewed from the front surface 40a of the silicon substrate 40, the position of the cutout part 142A on the side of the front surface 40a and the position of the cutout part 142B on the side of the rear surface 40b are shifted from each other by 180 degrees with respect to the central conductor 110. However, the positional relation of them is not limited to the aforementioned one. For example, the position of the cutout part 142A on the side of the front surface 40a and the position of the cutout part 142B on the side of the rear surface 40b may be shifted from each other by 90 degrees with respect to the central conductor 110. At this time, for example, the position of the cutout part 142B on the side of the rear surface 40b may be on the upper side (or the lower side) of the central conductor 110 in FIG. 20. In this manner, the orientations of the cutout parts 142A and 142B with respect to the central conductor 110 on the front surface 40a and the rear surface 40b may be adjusted to desired directions.

The through electrode 100 according to the third example embodiment described above is configured in such a way that the cutout parts 142A and 142B are provided in the external conductor 140. Therefore, the wiring substrate 50 according to the third example embodiment is able to achieve effects that are substantially similar to those of the wiring substrate 50 according to the second example embodiment.

Further, as described above, in the external conductor 140 according to the third example embodiment, the orientation of the position of the cutout part 142A in the front surface 40a with respect to the central conductor 110 is different from the orientation of the position of the cutout part 142B in the rear surface 40b with respect to the central conductor 110. Therefore, the wiring substrate 50 according to the third example embodiment is able to change the direction of the wire drawn from the central conductor 110 of the through electrode 100 to a desired direction. Therefore, the flexibility in wiring design is increased.

(Method of Manufacturing Wiring Substrate According to Example Embodiments)

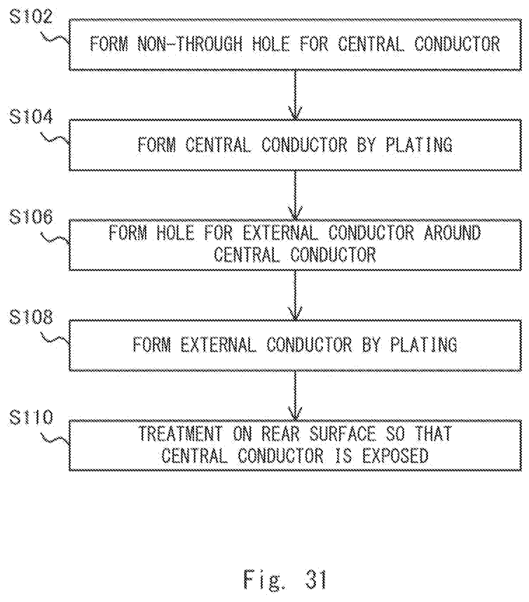

FIG. 31 is a flowchart showing a method of manufacturing the wiring substrate 50 according to the example embodiments. First, by performing a surface treatment on the front surface 40a (the first surface) of the silicon substrate 40 formed of silicon whose electrical resistivity is 1000 Ω·cm or larger, the non-through hole for the central conductor is formed (Step S102). This process corresponds to FIGS. 5 and 22. Next, the non-through hole is filled with conductors by plating, whereby the central conductor is formed (Step S104). This process corresponds to FIGS. 6-7 and 24-25.

At least the rear surface 40b (the second surface) of the silicon substrate 40 is processed, whereby at least one hole for the external conductor is formed around the central conductor (Step S106). This process corresponds to FIGS. 9, 23, and 27. Next, the hole for the external conductor is filled with conductors by plating, whereby the external conductor is formed (Step S108). This process corresponds to FIGS. 10, 24-25, and 28-29. Then, the rear surface 40b is subjected to a surface treatment in such a way that the central conductor is exposed in the rear surface 40b of the silicon substrate 40 (Step S110). This process corresponds to FIGS. 11 and 30.

According to the aforementioned manufacturing method, the central conductor can be formed in the silicon substrate 40, and the external conductor can be formed around it in such a way that there is a space between the external conductor and the central conductor. Therefore, it is possible to easily manufacture the wiring substrate 50 in which the through electrode 100 is formed in the silicon substrate 40, the central conductor and the external conductor being electrically insulated from each other in the through electrode 100 by the silicon substrate 40 formed of a high-resistance silicon. Further, since the external conductor having a high aspect ratio can be formed according to the aforementioned method, the through electrodes 100 may be integrated in a high density in the silicon substrate 40.

### Modified Example

Note that the present invention is not limited to the aforementioned example embodiments and may be changed as appropriate without departing from the spirit of the present invention. For example, one or more of the processes of each step in the aforementioned flowchart may be omitted. Further, the order of the steps in the aforementioned flowchart may be changed as appropriate. Further, each of the aforementioned steps may be performed concurrently with other steps. For example, in the flowchart shown in FIG. 31, the processes in S106-S108 may be performed concurrently with the processes in S102-S104. Alternatively, the process in S106 may be executed prior to the process in S104.

Further, in the manufacturing processes according to the aforementioned example embodiments, the front surface 40a and the rear surface 40b may be reversed. That is, in the aforementioned example embodiments, in the method of manufacturing the wiring substrate 50, the central conductor is formed by forming the non-through hole in the front surface 40a (the first surface) of the silicon substrate 40 and the external conductor is formed by forming the hole for the external conductor in the rear surface 40b (the second surface) of the silicon substrate 40. However, the central conductor may be formed by forming the non-through hole in the rear surface 40b (the first surface) of the silicon substrate 40 and the external conductor may be formed by forming the hole for the external conductor in the front surface 40a (the second surface) of the silicon substrate 40.

Further, while the non-through hole and the holes for the external conductors are formed by etching in the aforementioned example embodiments, the method of forming the holes is not limited to etching. Further, while the seed layers are formed by sputtering in the aforementioned example embodiments, the method of forming the seed layers is not limited to sputtering.

While the present invention has been described above with reference to the example embodiments, the present invention is not limited by the aforementioned descriptions. Various changes that can be understood by one skilled in the art may be made within the scope of the invention to the configurations and the details of the present invention.

Further, the whole or part of the above example embodiments can be described as, but not limited to, the following supplementary notes.

(Supplementary Note 1)

A wiring substrate comprising:

a silicon substrate formed of silicon whose electrical resistivity is 1000 Ω·cm or larger; and

a through electrode formed in the silicon substrate, wherein

the through electrode is formed of a central conductor that penetrates through the silicon substrate and an external conductor formed around the central conductor, and

the central conductor and the external conductor are electrically insulated from each other by the silicon substrate.

(Supplementary Note 2)

The wiring substrate according to Supplementary Note 1, wherein the width of the external conductor is 0.5 times as large or smaller than the outer dimension of the central conductor.

(Supplementary Note 3)

The wiring substrate according to Supplementary Note 1 or 2, wherein the external conductor is formed around the central conductor in such a way that the external conductor has a continuous ring shape.

(Supplementary Note 4)

The wiring substrate according to Supplementary Note 1 or 2, wherein the external conductor is formed to surround the central conductor in such a way that the external conductor has a ring shape in which a part of it is cut out.

(Supplementary Note 5)

The wiring substrate according to Supplementary Note 4, wherein a separation distance of a part in which the external conductor is cut out is equal to or smaller than the diameter of the central conductor.

(Supplementary Note 6)

The wiring substrate according to one of Supplementary Notes 1 to 5, wherein the external conductor is formed to have a continuous shape in a thickness direction of the silicon substrate.

(Supplementary Note 7)

The wiring substrate according to Supplementary Note 1 or 2, wherein the external conductor includes a first external conductor part formed on a side of a first surface of the silicon substrate and a second external conductor part that is formed on a second surface, which is a surface opposite to the first surface of the silicon substrate and is electrically connected to the first external conductor part,

the first external conductor part is formed to surround the central conductor in such a way that the first external conductor part has a ring shape in which a part of it at a first position is cut out,

the second external conductor part is formed to surround the central conductor in such a way that the second external conductor part has a ring shape in which a part of it at a second position is cut out, and

the first position with respect to the central conductor is different from the second position with respect to the central conductor.

(Supplementary Note 8)

The wiring substrate according to Supplementary Note 7, wherein the external conductor further includes a third external conductor part between the first external conductor part and the second external conductor part, the third external conductor part being formed to surround the central conductor in such a way that the third external conductor part has a continuous ring shape.

(Supplementary Note 9)

A method of manufacturing a wiring substrate, the method comprising:

forming a non-through hole for a central conductor of a through electrode by performing a surface treatment on a first surface of a silicon substrate formed of silicon whose electrical resistivity is 1000 Ω·cm or larger;

forming the central conductor by filling the non-through hole with conductors by plating;

forming at least one hole for an external conductor, which is a hole for an external conductor of the through electrode, around the central conductor by performing a surface treatment on at least a second surface, which is a surface opposite to the first surface of the silicon substrate;

forming the external conductor by filling the hole for the external conductor with conductors by plating; and

performing a surface treatment on the second surface in such a way that the central conductor is exposed in the second surface.

(Supplementary Note 10)

The method of manufacturing the wiring substrate according to Supplementary Note 9, comprising, by plating the first surface, filling the non-through hole with conductors and forming the central conductor, and forming a conductor film around the central conductor in the first surface.

(Supplementary Note 11)

The method of manufacturing the wiring substrate according to Supplementary Note 10, comprising, by performing a surface treatment on the conductor film, forming an electrode of the central conductor in the first surface, and then forming a ground plane around the central conductor in the first surface.

(Supplementary Note 12)

The method of manufacturing the wiring substrate according to Supplementary Note 11, comprising:

forming the hole for the external conductor so that it extends from the second surface to the ground plane formed on the first surface; and

by connecting the ground plane to an electrode and filling the hole for the external conductor with conductors by plating, forming the external conductor to surround the central conductor in such a way that the external conductor has a continuous ring shape or a ring shape in which a part of the external conductor is cut out.

(Supplementary Note 13)

The method of manufacturing the wiring substrate according to Supplementary Note 11 or 12, comprising:

forming the hole for the external conductor so that it extends from the second surface to the ground plane formed on the first surface; and

by connecting the ground plane to an electrode and filling the hole for the external conductor with conductors by plating, forming the external conductor in a continuous shape in a thickness direction of the silicon substrate.

(Supplementary Note 14)

The method of manufacturing the wiring substrate according to Supplementary Note 9, comprising:

by performing a surface treatment on the first surface, forming a first hole for an external conductor, which is a hole for the external conductor, having a depth shallower than that of the non-through hole and having a C shape when it is viewed from the first surface, around the non-through hole; and

by plating the first surface, forming the central conductor by filling the non-through hole with conductors, and filling the first hole for the external conductor with conductors, thereby forming a first external conductor part, which is a part of the external conductor, to surround the central conductor in such a way that the first external conductor part has a ring shape in which a part of the first external conductor part in a first position is cut out.

(Supplementary Note 15)

The method of manufacturing the wiring substrate according to Supplementary Note 14, comprising:

forming a first seed layer on the first surface in a state in which the non-through hole and the first hole for the external conductor are formed in the first surface; and

forming the central conductor and the first external conductor part by connecting the first seed layer to an electrode and plating the first seed layer.

(Supplementary Note 16)

The method of manufacturing the wiring substrate according to Supplementary Note 15, comprising:

by performing a surface treatment on the second surface, forming a second hole for an external conductor, which is a hole for the external conductor, having a depth shallower than the non-through hole and having a C shape when it is viewed from the second surface, around the central conductor; and

by plating the second surface, filling the second hole for the external conductor with conductors, thereby forming a second external conductor part, which is a part of the external conductor, to surround the central conductor in such a way that the second external conductor part has a ring shape in which a part of the second external conductor part in a second position is cut out, which position with respect to the central conductor is different from that of the first position.

(Supplementary Note 17)

The method of manufacturing the wiring substrate according to Supplementary Note 16, comprising:

forming a second seed layer on the second surface in a state in which the second hole for the external conductor is formed in the second surface; and

forming the second external conductor part by connecting the second seed layer to an electrode and plating the second seed layer.

(Supplementary Note 18)

The method of manufacturing the wiring substrate according to Supplementary Note 16 or 17, wherein the total of the depth of the first hole for the external conductor and the depth of the second hole for the external conductor is equal to or larger than the thickness of the silicon substrate.

### REFERENCE SIGNS LIST

1 Superconducting Circuit Device
2 Superconducting Circuit Mounting Structure
3 Readout Unit
4 Control Unit
10 Bump
12 Capacitive Coupling
14 Inductive Coupling
20 Quantum Circuit Chip
22 Quantum Circuit
24 Electrode
30 Wire
40 Silicon Substrate
40a Front Surface
40b Rear Surface
42, 44, 46, 48 Electrode
50 Wiring Substrate
100 Through Electrode
102 Insulating Layer
110 Central Conductor
120, 130, 140 External Conductor
132, 142A, 142B Cutout Part
140a, 140b, 140c External Conductor Part
200, 250 Seed Layer
201, 230, 251 Conductor Film
202 Pad
204 Ground Plane
210 Non-through Hole
220, 241, 242 Hole for External Conductor

What is claimed is:

1. A wiring substrate comprising:
a silicon substrate formed of silicon whose electrical resistivity is 1000 Ω·cm or larger; and
a through electrode formed in the silicon substrate, wherein
the through electrode is formed of a central conductor that penetrates through the silicon substrate and an external conductor formed around the central conductor, and
the central conductor and the external conductor are electrically insulated from each other by the silicon substrate.

2. The wiring substrate according to claim 1, wherein the width of the external conductor is 0.5 times as large or smaller than the outer dimension of the central conductor.

3. The wiring substrate according to claim 1, wherein the external conductor is formed around the central conductor in such a way that the external conductor has a continuous ring shape.

4. The wiring substrate according to claim 1, wherein the external conductor is formed to surround the central conductor in such a way that the external conductor has a ring shape in which a part of it is cut out.

5. The wiring substrate according to claim 4, wherein a separation distance of a part in which the external conductor is cut out is equal to or smaller than the diameter of the central conductor.

6. The wiring substrate according to claim 1, wherein the external conductor is formed to have a continuous shape in a thickness direction of the silicon substrate.

7. The wiring substrate according to claim 1, wherein
the external conductor includes a first external conductor part formed on a side of a first surface of the silicon substrate and a second external conductor part that is formed on a second surface, which is a surface opposite to the first surface of the silicon substrate and is electrically connected to the first external conductor part,
the first external conductor part is formed to surround the central conductor in such a way that the first external conductor part has a ring shape in which a part of it at a first position is cut out,
the second external conductor part is formed to surround the central conductor in such a way that the second external conductor part has a ring shape in which a part of it at a second position is cut out, and
the first position with respect to the central conductor is different from the second position with respect to the central conductor.

8. The wiring substrate according to claim 7, wherein the external conductor further includes a third external conductor part between the first external conductor part and the second external conductor part, the third external conductor part being formed to surround the central conductor in such a way that the third external conductor part has a continuous ring shape.

9. A method of manufacturing a wiring substrate, the method comprising:
forming a non-through hole for a central conductor of a through electrode by performing a surface treatment on a first surface of a silicon substrate formed of silicon whose electrical resistivity is 1000 Ω·cm or larger;
forming the central conductor by filling the non-through hole with conductors by plating;
forming at least one hole for an external conductor, which is a hole for an external conductor of the through electrode, around the central conductor by performing a surface treatment on at least a second surface, which is a surface opposite to the first surface of the silicon substrate;
forming the external conductor by filling the hole for the external conductor with conductors by plating; and
performing a surface treatment on the second surface in such a way that the central conductor is exposed in the second surface.

10. The method of manufacturing the wiring substrate according to claim 9, comprising, by plating the first surface, filling the non-through hole with conductors and forming the central conductor, and forming a conductor film around the central conductor in the first surface.

11. The method of manufacturing the wiring substrate according to claim 10, comprising, by performing a surface treatment on the conductor film, forming an electrode of the central conductor in the first surface, and then forming a ground plane around the central conductor in the first surface.

12. The method of manufacturing the wiring substrate according to claim 11, comprising:
forming the hole for the external conductor so that it extends from the second surface to the ground plane formed on the first surface; and
by connecting the ground plane to an electrode and filling the hole for the external conductor with conductors by plating, forming the external conductor to surround the central conductor in such a way that the external conductor has a continuous ring shape or a ring shape in which a part of the external conductor is cut out.

13. The method of manufacturing the wiring substrate according to claim 11, comprising:
forming the hole for the external conductor so that it extends from the second surface to the ground plane formed on the first surface; and
by connecting the ground plane to an electrode and filling the hole for the external conductor with conductors by plating, forming the external conductor in a continuous shape in a thickness direction of the silicon substrate.

14. The method of manufacturing the wiring substrate according to claim 9, comprising:
by performing a surface treatment on the first surface, forming a first hole for an external conductor, which is a hole for the external conductor, having a depth shallower than that of the non-through hole and having a C shape when it is viewed from the first surface, around the non-through hole; and
by plating the first surface, forming the central conductor by filling the non-through hole with conductors, and filling the first hole for the external conductor with conductors, thereby forming a first external conductor part, which is a part of the external conductor, to surround the central conductor in such a way that the first external conductor part has a ring shape in which a part of the first external conductor part in a first position is cut out.

15. The method of manufacturing the wiring substrate according to claim 14, comprising:
forming a first seed layer on the first surface in a state in which the non-through hole and the first hole for the external conductor are formed in the first surface; and
forming the central conductor and the first external conductor part by connecting the first seed layer to an electrode and plating the first seed layer.

16. The method of manufacturing the wiring substrate according to claim 15, comprising:
by performing a surface treatment on the second surface, forming a second hole for an external conductor, which is a hole for the external conductor, having a depth shallower than the non-through hole and having a C shape when it is viewed from the second surface, around the central conductor; and
by plating the second surface, filling the second hole for the external conductor with conductors, thereby forming a second external conductor part, which is a part of the external conductor, to surround the central conductor in such a way that the second external conductor part has a ring shape in which a part of the second external conductor part in a second position is cut out, which position with respect to the central conductor is different from that of the first position.

17. The method of manufacturing the wiring substrate according to claim 16, comprising:
forming a second seed layer on the second surface in a state in which the second hole for the external conductor is formed in the second surface; and
forming the second external conductor part by connecting the second seed layer to an electrode and plating the second seed layer.

18. The method of manufacturing the wiring substrate according to claim 16, wherein the total of the depth of the first hole for the external conductor and the depth of the second hole for the external conductor is equal to or larger than the thickness of the silicon substrate.
